(19) United States
(12) Patent Application Publication
(10) Pub. No.: US 2026/0323996 A1
(43) Pub. Date: Oct. 15, 2026

(54) SEMICONDUCTOR DEVICE COMPRISING CONNECTIONS THROUGH STACKED TRANSISTORS FOR ROUTING FLEXIBILITY

(71) Applicant: TAIWAN SEMICONDUCTOR MANUFACTURING COMPANY LTD., HSINCHU (TW)

(72) Inventors: SHIH-WEI PENG, HSINCHU CITY (TW); CHUN-YEN LIN, HSINCHU CITY (TW); WEI-CHENG TZENG, TAIPEI (TW); JIANN-TYNG TZENG, HSINCHU (TW)

(21) Appl. No.: 19/723,014

(22) Filed: Jun. 29, 2026

Related U.S. Application Data
(63) Continuation of application No. 17/749,160, filed on May 20, 2022, now Pat. No. 12,751,045.

(51) Int. Cl. H10D 30/67; H10D 62/10; H10D 84/01; H10D 84/03; H10D 84/83

(52) U.S. Cl. CPC H10D 30/6729; H10D 30/6713; H10D 30/6757; H10D 62/118; H10D 84/013; H10D 84/038; H10D 84/834

(57) ABSTRACT

A semiconductor device includes a first transistor, a second transistor, a third transistor, and a contact. The first transistor includes a first source/drain (S/D), a second S/D, and a first gate between the first S/D and the second S/D. The first transistor and the second transistor are stacked over the third transistor. The contact covers the second S/D of the first transistor. The contact is electrically connected to the second transistor and electrically isolated from the second S/D.

### CROSS-REFERENCE TO RELATED APPLICATIONS

This application is a continuation application of non-provisional application Ser. 17/749,160 filed on May 20, 2022, entitled "SEMICONDUCTOR DEVICE COMPRISING CONNECTIONS THROUGH STACKED TRANSISTORS FOR ROUTING FLEXIBILITY," the disclosure of which is hereby incorporated by reference in its entirety.

### BACKGROUND

Integrated circuits (ICs) are often designed to implement various devices, including, for example, transistors, resistors, capacitors, or the like. These devices are often designed using connections of conductive traces to form circuits. Increasingly dense ICs result in benefits in terms of speed, functionality and cost, but cause increasingly difficult design and fabrication issues.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a top view of a semiconductor device in accordance with some embodiments of the present disclosure.

FIG. 1B is a cross-sectional view of a semiconductor device in accordance with some embodiments of the present disclosure.

FIG. 1C is a cross-sectional view of a semiconductor device in accordance with some embodiments of the present disclosure.

FIG. 1D is a cross-sectional view of a semiconductor device in accordance with some embodiments of the present disclosure.

FIGS. 2A to 9D are schematic views of intermediate stages of a method of manufacturing a semiconductor device in accordance with some embodiments of the present disclosure.

FIG. 10A is a top view of a semiconductor device in accordance with some embodiments of the present disclosure.

FIG. 10B is a cross-sectional view of a semiconductor device in accordance with some embodiments of the present disclosure.

FIG. 10C is a cross-sectional view of a semiconductor device in accordance with some embodiments of the present disclosure.

FIG. 10D is a cross-sectional view of a semiconductor device in accordance with some embodiments of the present disclosure.

FIG. 10E illustrates a schematic view of a circuit in accordance with some embodiments of the present disclosure.

FIGS. 11A to 14C are schematic views of intermediate stages of a method of manufacturing a semiconductor device in accordance with some embodiments of the present disclosure.

FIG. 15A is a top view of a semiconductor device in accordance with some embodiments of the present disclosure.

FIG. 15B is a cross-sectional view of a semiconductor device in accordance with some embodiments of the present disclosure.

FIG. 15C is a cross-sectional view of a semiconductor device in accordance with some embodiments of the present disclosure.

FIG. 15D is a cross-sectional view of a semiconductor device in accordance with some embodiments of the present disclosure.

FIG. 15E is a cross-sectional view of a semiconductor device in accordance with some embodiments of the present disclosure.

FIG. 15F illustrates a schematic view of a circuit in accordance with some embodiments of the present disclosure.

FIG. 16A is a top view of a semiconductor device in accordance with some embodiments of the present disclosure.

FIG. 16B is a cross-sectional view of a semiconductor device in accordance with some embodiments of the present disclosure.

FIG. 16C is a cross-sectional view of a semiconductor device in accordance with some embodiments of the present disclosure.

FIG. 16D illustrates a schematic view of a circuit in accordance with some embodiments of the present disclosure.

FIG. 17A is a top view of a semiconductor device in accordance with some embodiments of the present disclosure.

FIG. 17B is a cross-sectional view of a portion of a semiconductor device in accordance with some embodiments of the present disclosure.

FIG. 17C is a cross-sectional view of a portion of a semiconductor device in accordance with some embodiments of the present disclosure.

FIG. 17D illustrates a schematic view of a circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Embodiments of the present disclosure discuss semiconductor devices including a contact covering and electrically isolating from a source/drain (S/D) of one transistor while electrically connecting to one or more conductive features of another transistor(s). As such, the contact can serve to electrically connect conductive features of different transistors that are across over one or more gates, offset in an extending direction of the gates, or at different elevations. Therefore, the routing flexibility can be increased, and the number of layers of conductive traces can be reduced.

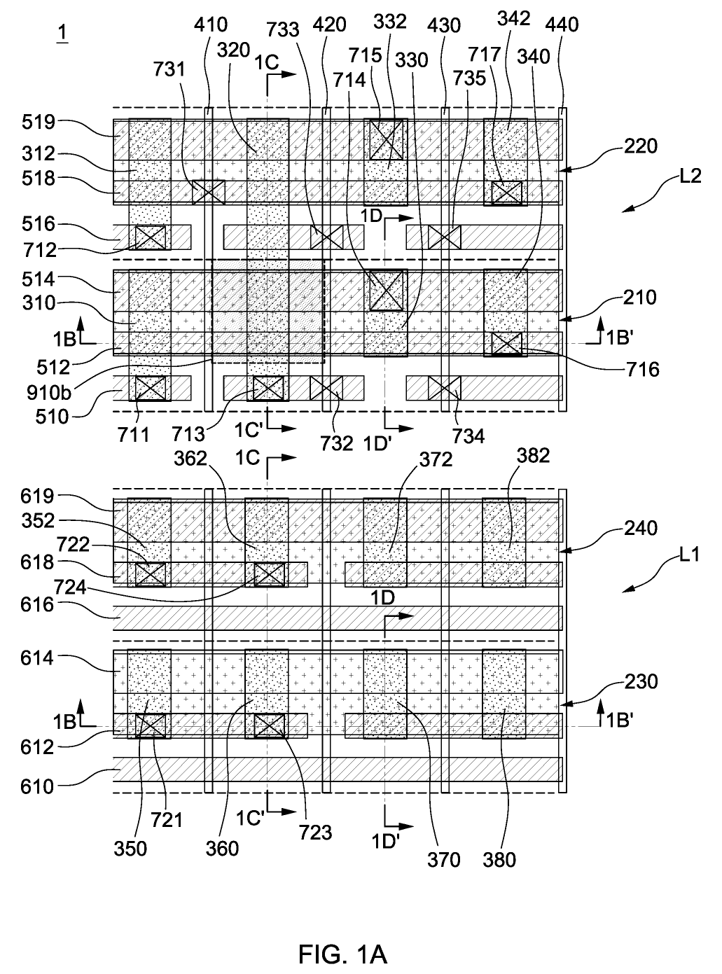

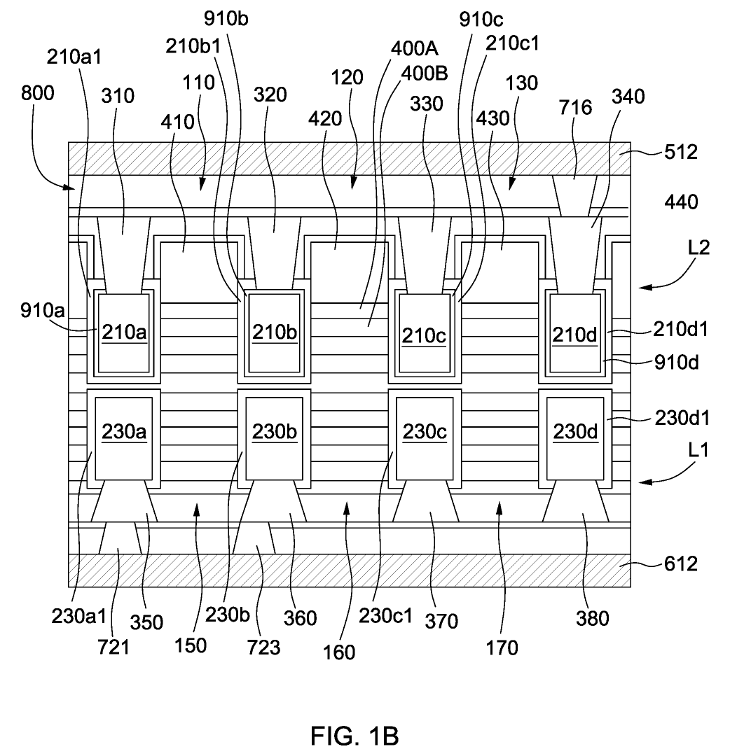

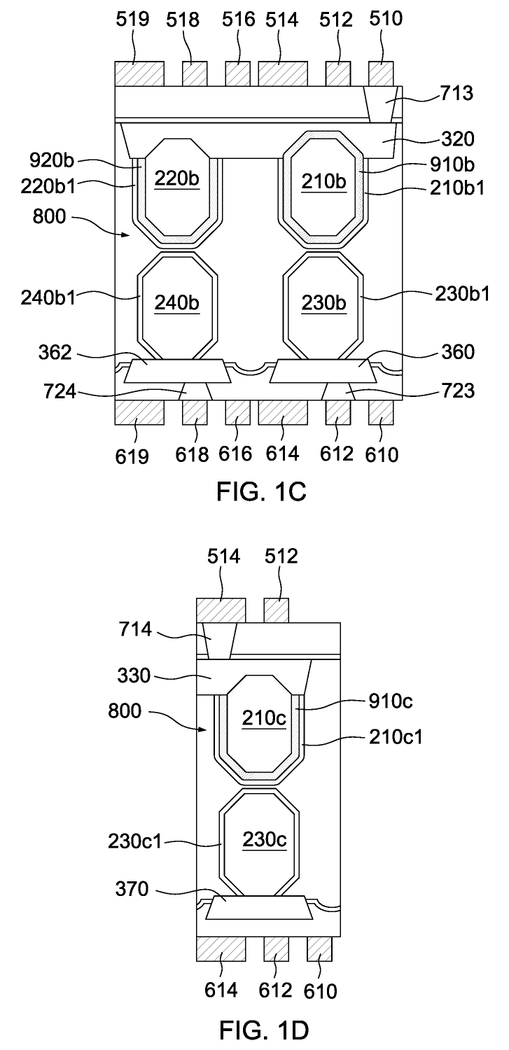

FIG. 1A is a top view of a semiconductor device 1 in accordance with some embodiments of the present disclosure. FIG. 1B is a cross-sectional view of a semiconductor device 1 in accordance with some embodiments of the present disclosure. FIG. 1C is a cross-sectional view of a semiconductor device 1 in accordance with some embodiments of the present disclosure. FIG. 1D is a cross-sectional view of a semiconductor device 1 in accordance with some embodiments of the present disclosure. In some embodiments, FIG. 1B illustrates a cross-sectional view along the cross-sectional line 1B-1B' in FIG. 1A, FIG. 1C illustrates a cross-sectional view along the cross-sectional line 1C-1C' in FIG. 1A, and FIG. 1D illustrates a cross-sectional view along the cross-sectional line 1D-1D' in FIG. 1A. In some embodiments, FIG. 1A illustrates a top view of a lower layer L1 and a top view of an upper layer L2 of the semiconductor device 1.

Referring to FIGS. 1A-1D, the semiconductor device 1 may be a portion of a standard cell. The semiconductor device 1 may include at least transistors 110, 112, 120, 130, 150, 160, and 170. In some embodiments, the transistors 110, 112, 120, and 130 are stacked over the transistors 150, 160, and 170. The transistors 110, 112, 120, and 130 may have the same conductivity type, and the transistors 150, 160, and 170 may have the same conductivity type. The transistors at the lower layer L1 and the transistors at the upper layer L2 may have opposite conductivity types. In some embodiments, the transistors 110, 112, 120, and 130 are n-type transistors, and the transistors 150, 160, and 170 are p-type transistors, and vice versa.

Referring to FIGS. 1A-1D, the layout structure of the semiconductor device 1 may include active regions 210, 220, 230, and 240, contacts 310, 312, 320, 330, 332, 340, 342, 350, 352, 360, 362, 370, 372, 380, and 382 (also referred to as "source/drain (S/D) contacts"), and gates 410, 420, 430, and 440. Each of the active regions may include conductive segments (e.g., epitaxial structures). For example, the active region 210 may include conductive segments 210a, 210b, 210c, and 210d, the active region 220 may include conductive segments 220a and 220b, the active region 230 may include conductive segments 230a, 230b, 230c, and 230d, and the active region 240 may include conductive segments 240a, 240b, 240c, and 240d. In some embodiments, each of the conductive segments may include a conductive layer (e.g., an epitaxial layer) and a spacer layer covering the conductive layer. The spacer layer may be or include silicon nitride. For example, the conductive segment 210a may include a conductive layer and a spacer layer 210a1 covering the conductive layer, the conductive segment 210b may include a conductive layer and a spacer layer 210b1 covering the conductive layer, the conductive segment 210c may include a conductive layer and a spacer layer 210c1 covering the conductive layer, the conductive segment 210d may include a conductive layer and a spacer layer 210d1 covering the conductive layer, the conductive segment 220b may include a conductive layer and a spacer layer 220b1 covering the conductive layer, the conductive segment 230a may include a conductive layer and a spacer layer 230a1 covering the conductive layer, the conductive segment 230b may include a conductive layer and a spacer layer 230b1 covering the conductive layer, the conductive segment 230c may include a conductive layer and a spacer layer 230c1 covering the conductive layer, the conductive segment 230d may include a conductive layer and a spacer layer 230d1 covering the conductive layer, and the conductive segment 240b may include a conductive layer and a spacer layer 240b1 covering the conductive layer.

Referring to FIGS. 1A-1D, the conductive segments of the active regions may serve as source/drains (S/Ds) of the transistors. In some embodiments, the transistor 110 includes the gate 410 and the conductive segments 210a and 210b on opposite sides of the gate 410. In some embodiments, the transistor 112 includes the gate 410 and the conductive segments 220a and 220b on opposite sides of the gate 410. In some embodiments, the transistor 120 includes the gate 420 and the conductive segments 210b and 210c on opposite sides of the gate 420. In some embodiments, the transistor 130 includes the gate 430 and the conductive segments 210c and 210d on opposite sides of the gate 430. In some embodiments, the transistor 150 includes the gate 410 and the conductive segments 230a and 230b on opposite sides of the gate 410. In some embodiments, the transistor 160 includes the gate 420 and the conductive segments 230b and 230c on opposite sides of the gate 420. In some embodiments, the transistor 170 includes the gate 430 and the conductive segments 230c and 230d on opposite sides of the gate 430. In some embodiments, the gate 440 is a dummy gate. In some other embodiments, the gate 440 is a functional gate of a device adjacent to the cell of the semiconductor device 1.

Referring to FIGS. 1A-1D, the layout structure of the semiconductor device 1 may further include stacked channel structures each including nanosheet channels 400A and 400B. The nanosheet channels 400A and 400B may be epitaxial layers and include Si or SiGe. In some embodiments, the nanosheet channels 400A include Si, and the nanosheet channels 400B include SiGe. Each stack of the nanosheet channels 400A and 400B may be surrounded by a corresponding gate. In some embodiments, each stack of the nanosheet channels 400A and 400B is between adjacent conductive segments at the upper layer L2 and between adjacent conductive segments the lower layer L1. In some embodiments, Si nanosheet channels serve as the channel regions of the n-type transistors, and SiGe nanosheet channels serve as the channel regions of the p-type transistors.

Referring to FIGS. 1A-1D, the layout structure of the semiconductor device 1 may further include conductive traces 510, 512, 514, 516, 518, 519, 610, 612, 614, 616, 618, and 619, conductive vias 711, 712, 713, 714, 715, 716, 721, 722, 723, 724, 731, 732, 733, 734, and 735, and an insulation structure 800. In some embodiments, the conductive traces 510, 512, 514, 516, 518, and 519 are over and electrically connected to the transistors 110, 112, 120, and 130 at the upper layer L2, and the conductive traces 610, 612, 614, 616, 618, and 619 are under and electrically connected to the transistors 150, 160, and 170 at the lower layer L1. In some embodiments, the conductive vias 711, 712, 713, 714, 715, and 716 serve to electrically connect the S/D contacts (e.g., the contacts 310, 312, 320, 330, 332, 340, and 342) at the upper layer L2 to the conductive traces over the upper layer L2. In some embodiments, the conductive vias 721, 722, 723, and 724 serve to electrically connect the S/D contacts (e.g., the contacts 350, 352, 360, 362, 370, 372, 380, and 382) at the lower layer L1 to the conductive traces under the lower layer L1. In some embodiments, the conductive vias 731, 732, 733, 734, and 735 serve to electrically connect the gates to the conductive traces over the upper layer L2. In some embodiments, the insulation structure 800 covers the transistors, the S/D contacts, and the conductive vias. The insulation structure 800 may include a plurality of insulating layers, e.g., dielectric layers.

Referring to FIGS. 1A-1D, the layout structure of the semiconductor device 1 may further include at least isolation layers 910a, 910b, 910c, 910d, and 920b. In some embodiments, each of the isolation layers covers a corresponding conductive segment at the upper layer L2. For example, the isolation layer 910a may cover the conductive segment 210a, the isolation layer 910b may cover the conductive segment 210b, the isolation layer 910c may cover the conductive segment 210c, the isolation layer 910d may cover the conductive segment 210d, and the isolation layer 920b may cover the conductive segment 220b.

Referring to FIGS. 1A-1D, in some embodiments, the contact 320 covers and is electrically isolated from the conductive segment (or the S/D) 210b of the transistor 110, and the contact 320 is electrically connected to the transistor 120. In some embodiments, the contact 320 is electrically connected to the gate 420 of the transistor 120 through the conductive via 713, the conductive trace 510, and the conductive via 734. In some embodiments, the isolation layer 920b covers a surface of the conductive segment 210b and electrically isolates the contact 320 from the conductive segment 210b. In some embodiments, the isolation layer 920b is between and directly contacts the contact 320 and the conductive segment (or the S/D) 210b of the transistor 110.

Referring to FIGS. 1A-1D, in some embodiments, the contact 320 is electrically connected to transistor 112. In some embodiments, the contact 320 further covers the conductive segment (or the S/D) 220b of the transistor 112. In some embodiments, the contact 320 is electrically connected to the conductive segment (or the S/D) 220b of the transistor 112. In some embodiments, the isolation layer 920b has an opening exposing a portion of the conductive segment 220b which contacts and electrically connects to the contact 320. In some embodiments, the transistor 112 is offset from the transistor 120 in an extending direction of the gates, and the transistor 112 is electrically connected to the transistor 120 through the contact 320. In some embodiments, the conductive segment (or the S/D) 220b of the transistor 112 is electrically connected to the gate 420 of the transistor 120 through the contact 320, the conductive via 713, the conductive trace 510, and the conductive via 734.

In some embodiments, the conductive segment 210b is an internal common S/D or a shared S/D between different transistors. In some embodiments, the transistor 110 and the transistor 120 share the conductive segment 210b as a shared S/D. In some embodiments, the isolation layer 920b covers the conductive segment 210b (or the shared S/D), and the conductive segment 210b (or the shared S/D) is electrically isolated from an external connector. That is, there is not external connector electrically connected to the conductive segment 210b.

According to some embodiments of the present disclosure, with the aforesaid design, the contact 320 can extend over the conductive segment 210b to further electrically connect to conductive features in other transistors without arranging additional stacked conductive traces or vias. For example, the contact 320 can serve to electrically connect conductive features of two transistors that are across over one or more gates or that are offset in an extending direction of the gates. Therefore, the routing flexibility can be increased, and the number of layers of conductive traces can be reduced.

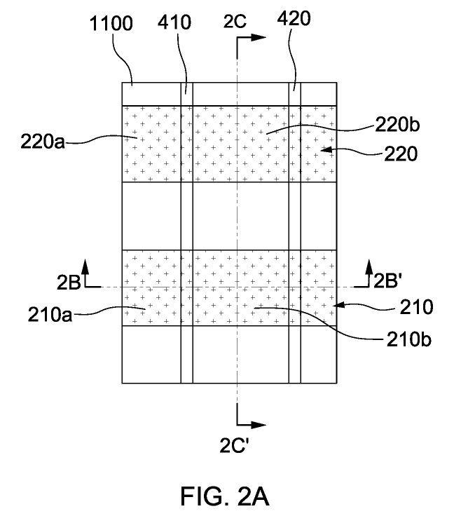

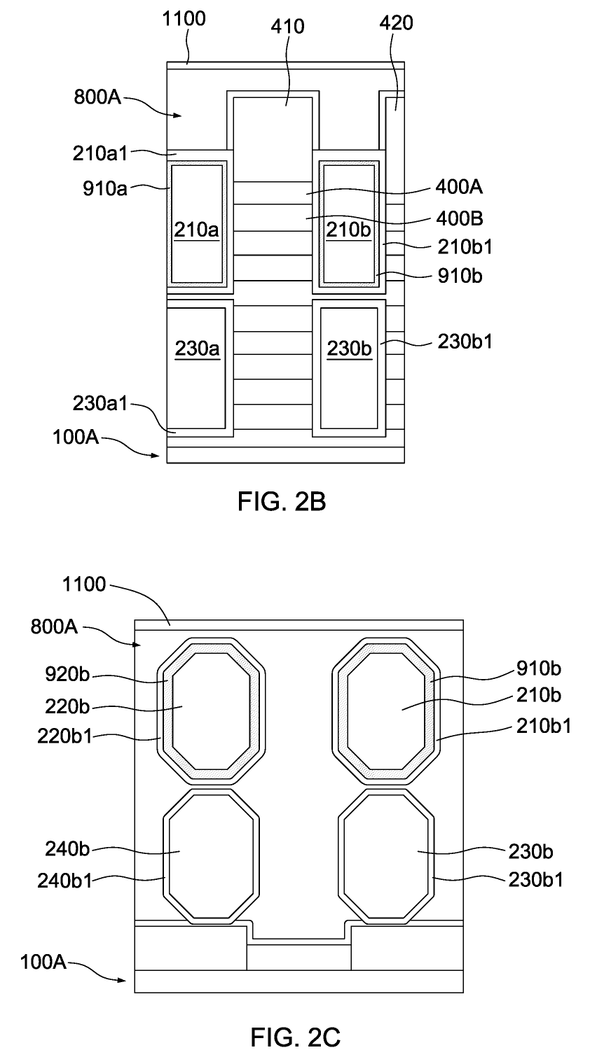

FIGS. 2A to 9D are schematic views of intermediate stages of a method of manufacturing a semiconductor device 1B in accordance with some embodiments of the present disclosure.

Referring to FIGS. 2A-2C, FIG. 2B illustrates a cross-sectional view along the cross-sectional line 2B-2B' in FIG. 2A, and FIG. 2C illustrates a cross-sectional view along the cross-sectional line 2C-2C' in FIG. 2A. In some embodiments, stacks of nanosheet channels 400A and 400B are formed over a substrate 100A, conductive segments 230a and 230b are formed on opposite sides of a stack of nanosheet channels 400A and 400B, and a conductive segment 240b is formed adjacent to the conductive segment 230b. In some embodiments, conductive segments 210a and 210b are formed over the conductive segments 230a and 230b and on opposite sides of the stack of nanosheet channels 400A and 400B, and a conductive segment 220b is formed over the conductive segment 240b. In some embodiments, gates 410 and 420 are formed on the stacks of nanosheet channels 400A and 400B, and an insulation structure 800A is formed covering the conductive segments 210a, 210b, 220a, 220b, 230a, 230b, and 240b, the nanosheet channels 400A and 400B, and the gates 410 and 420, and a hard mask 1100 is formed on the insulation structure 800A. In some embodiments, the insulation structure 800A includes an oxide layer, and the hard mask 1100 include silicon nitride. The substrate 100A may include a silicon layer over a buried oxide layer.

In some embodiments, the conductive segment 210a includes a conductive layer, an isolation layer 910a covering the conductive layer, and a spacer layer 210a1 covering the isolation layer 910a. In some embodiments, the conductive segment 210b includes a conductive layer, an isolation layer 910b covering the conductive layer, and a spacer layer 210b1 covering the isolation layer 910b. In some embodiments, the conductive segment 220b includes a conductive layer, an isolation layer 920b covering the conductive layer, and a spacer layer 220b1 covering the isolation layer 920b.

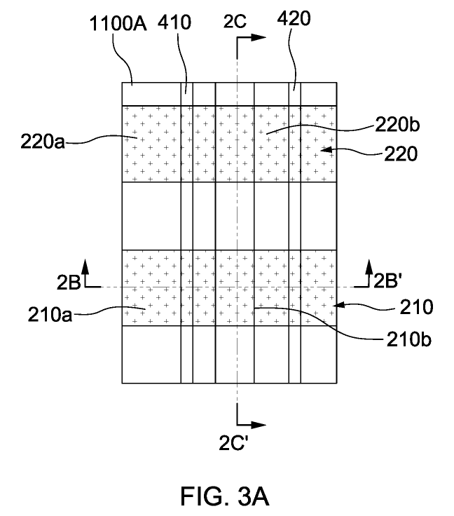

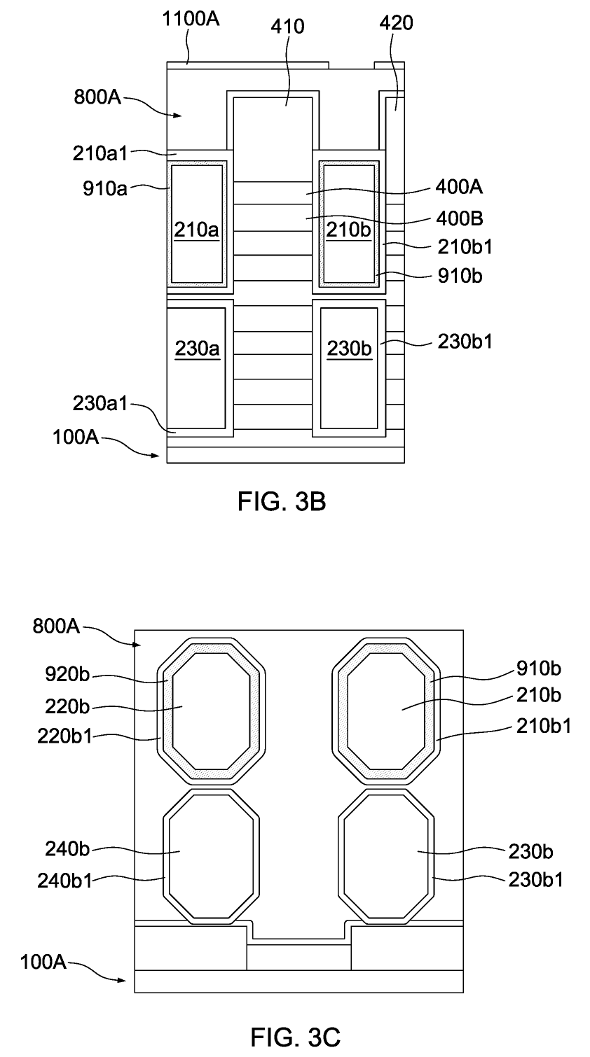

Referring to FIGS. 3A-3C, FIG. 3B illustrates a cross-sectional view along the cross-sectional line 2B-2B' in FIG. 3A, and FIG. 3C illustrates a cross-sectional view along the cross-sectional line 2C-2C' in FIG. 3A. In some embodiments, a patterning operation is performed on the hardmask 1100A to form a patterned hardmask 1100A having an opening exposing a portion of the insulation structure 800A. In some embodiments, the opening is directly above the conductive segments 210b and 220b. The patterning operation may be performed by etching.

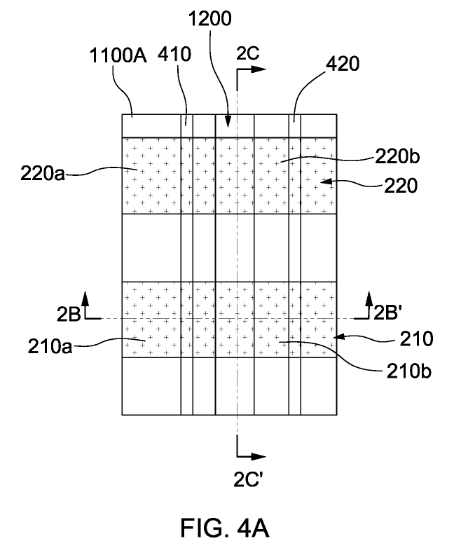

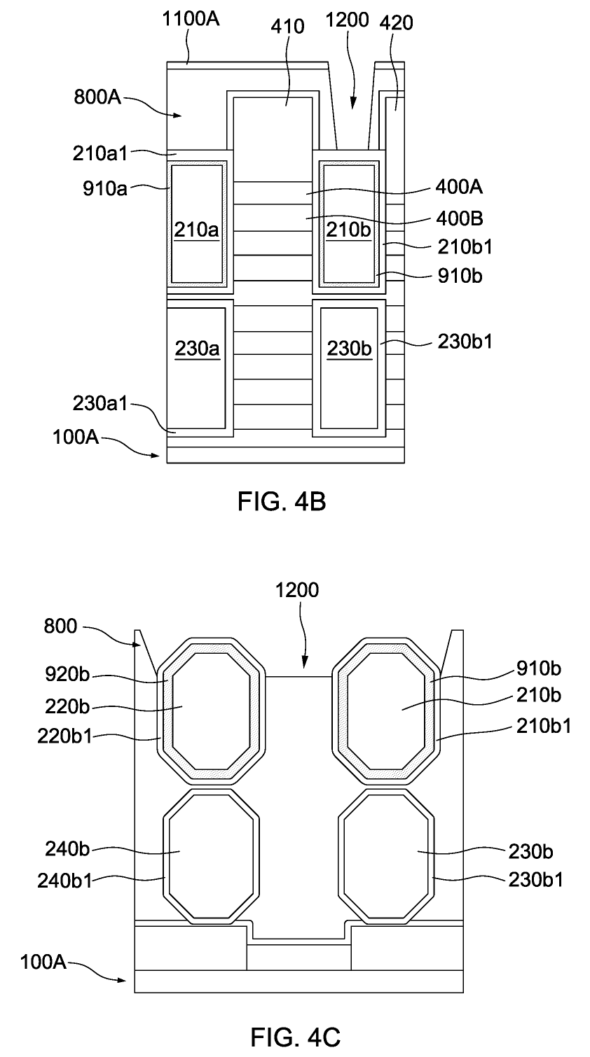

Referring to FIGS. 4A-4C, FIG. 4B illustrates a cross-sectional view along the cross-sectional line 2B-2B' in FIG. 4A, and FIG. 4C illustrates a cross-sectional view along the cross-sectional line 2C-2C' in FIG. 4A. In some embodiments, a trench 1200 may be formed passing through the insulation structure 800A and stopped at the spacer layer 210b1 of the conductive segment 210b and the spacer layer 220b1 of the conductive segment 220b. The trench 1200 may be formed by etching according to the opening of the patterned hard mask 1100A.

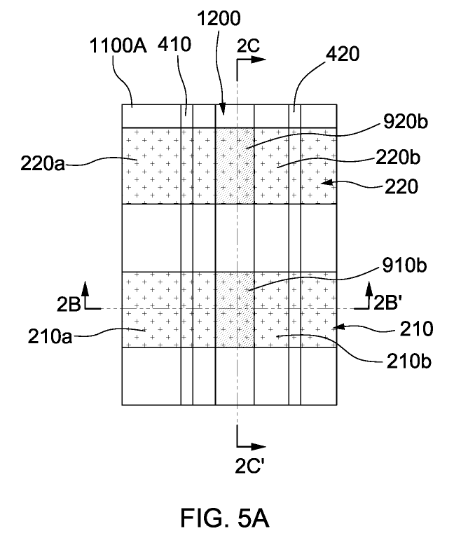

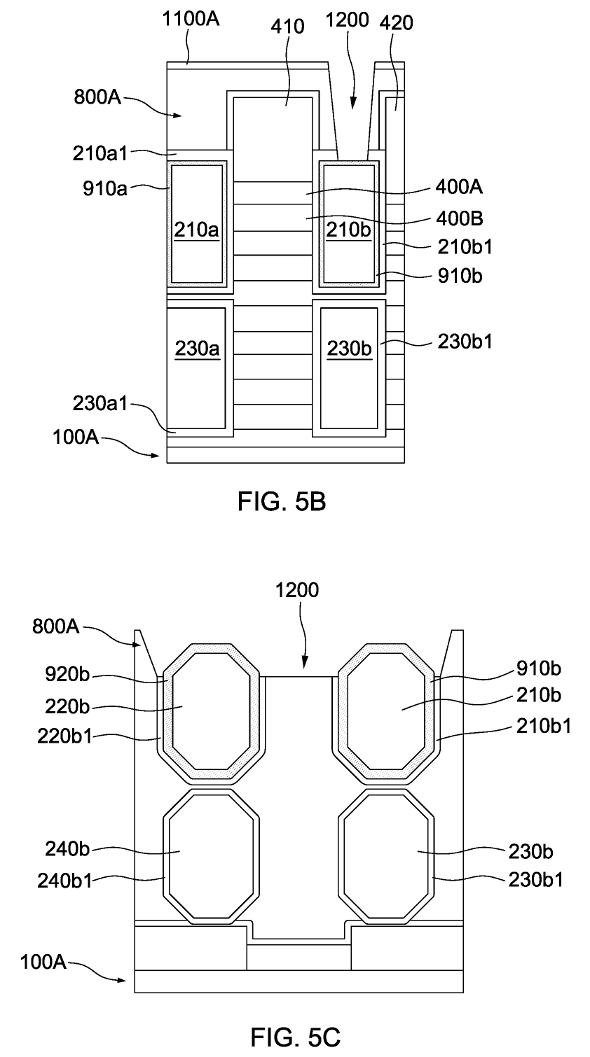

Referring to FIGS. 5A-5C, FIG. 5B illustrates a cross-sectional view along the cross-sectional line 2B-2B' in FIG. 5A, and FIG. 5C illustrates a cross-sectional view along the cross-sectional line 2C-2C' in FIG. 5A. In some embodiments, portions of the spacer layers 210b1 and 220b1 exposed to the trench 1200 are removed to exposed portions of the isolation layers 910b and 920b. The portions of the spacer layers 210b1 and 220b1 may be removed by etching.

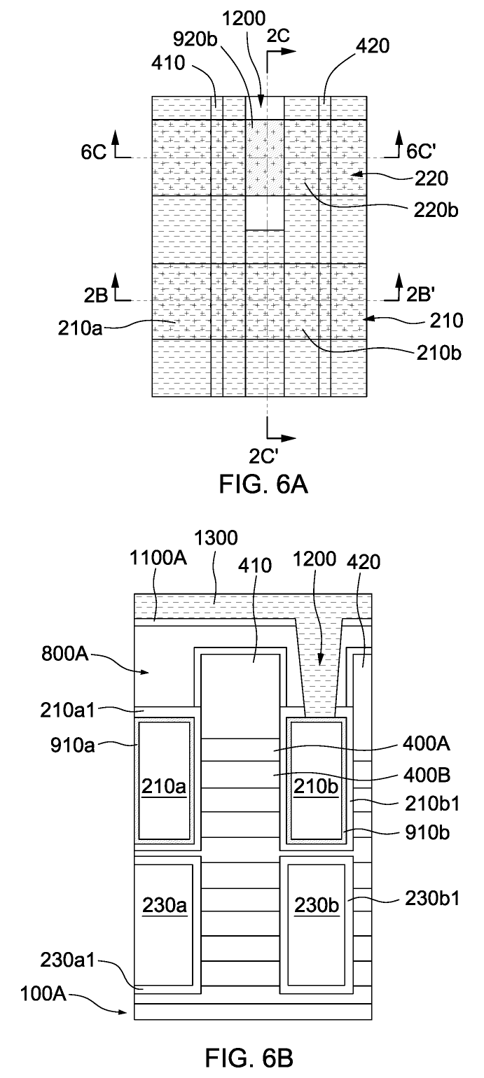

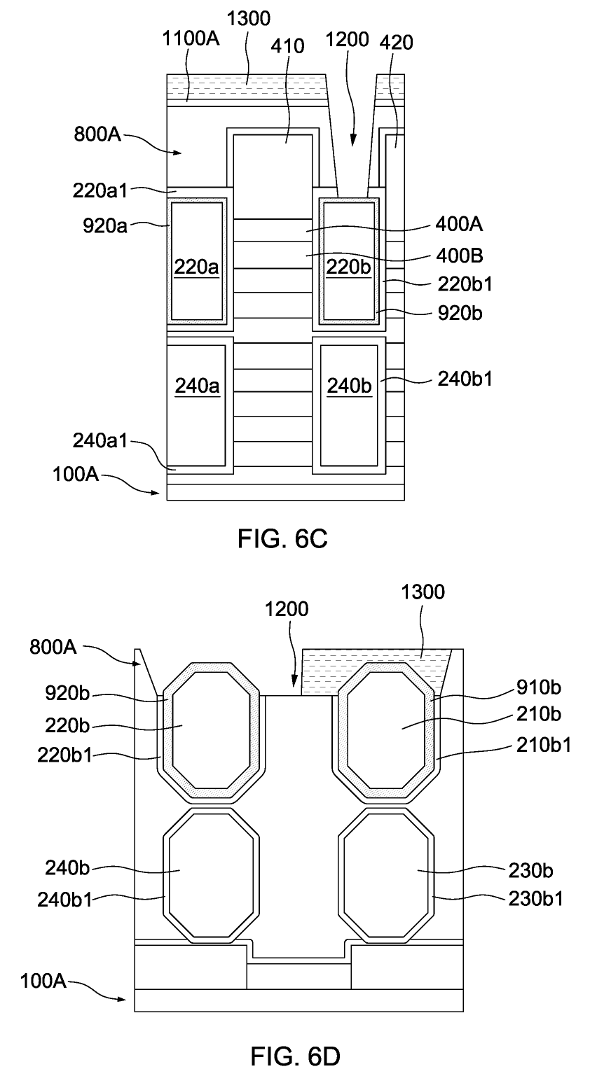

Referring to FIGS. 6A-6D, FIG. 6B illustrates a cross-sectional view along the cross-sectional line 2B-2B' in FIG. 6A, FIG. 6C illustrates a cross-sectional view along the cross-sectional line 6C-6C' in FIG. 6A, and FIG. 6D illustrates a cross-sectional view along the cross-sectional line 2C-2C' in FIG. 6A. In some embodiments, a protection layer 1300 is formed on the exposed portion of the isolation layer 910b in the trench 1200. In some embodiments, the protection layer 1300 entirely covers the exposed portion of the isolation layer 910b in the trench 1200. In some embodiments, the protection layer 1300 is free from covering or contacting the exposed portion of the isolation layer 920b. In some embodiments, the exposed portion of the isolation layer 920b is exposed to the trench 1200 by the protection layer 1300.

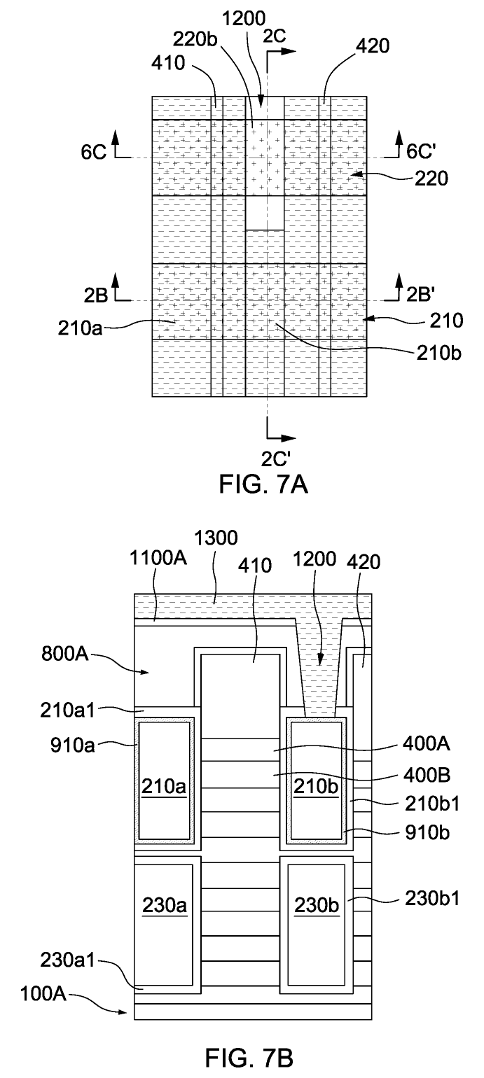

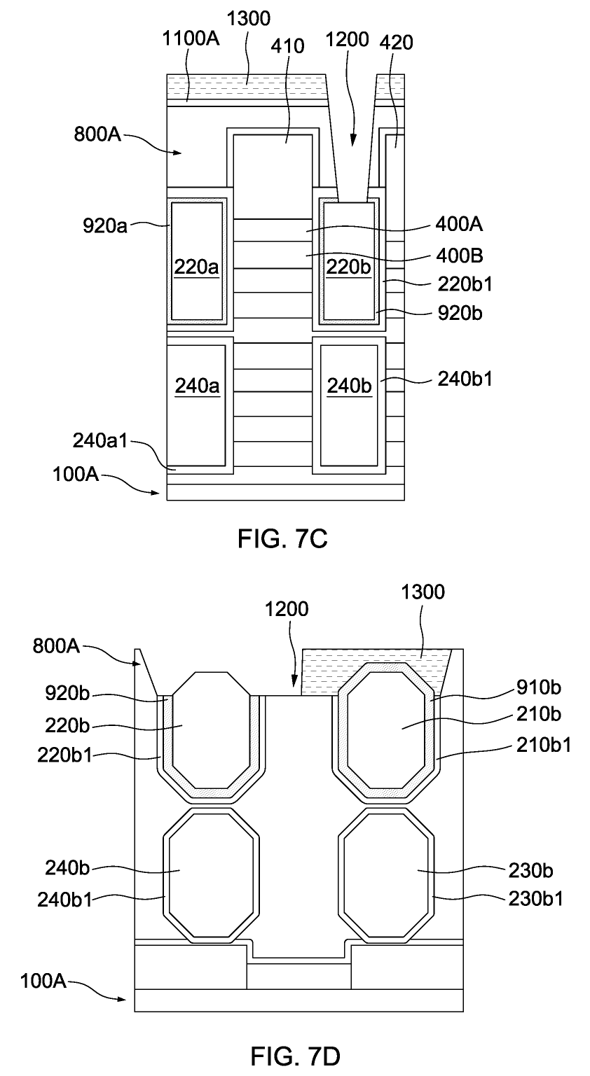

Referring to FIGS. 7A-7D, FIG. 7B illustrates a cross-sectional view along the cross-sectional line 2B-2B' in FIG. 7A, FIG. 7C illustrates a cross-sectional view along the cross-sectional line 6C-6C' in FIG. 7A, and FIG. 7D illustrates a cross-sectional view along the cross-sectional line 2C-2C' in FIG. 7A. In some embodiments, the exposed portion of the isolation layer 920b is removed to expose a portion of the conductive layer of the conductive segment 220b. The exposed portion of the isolation layer 920b may be removed by etching.

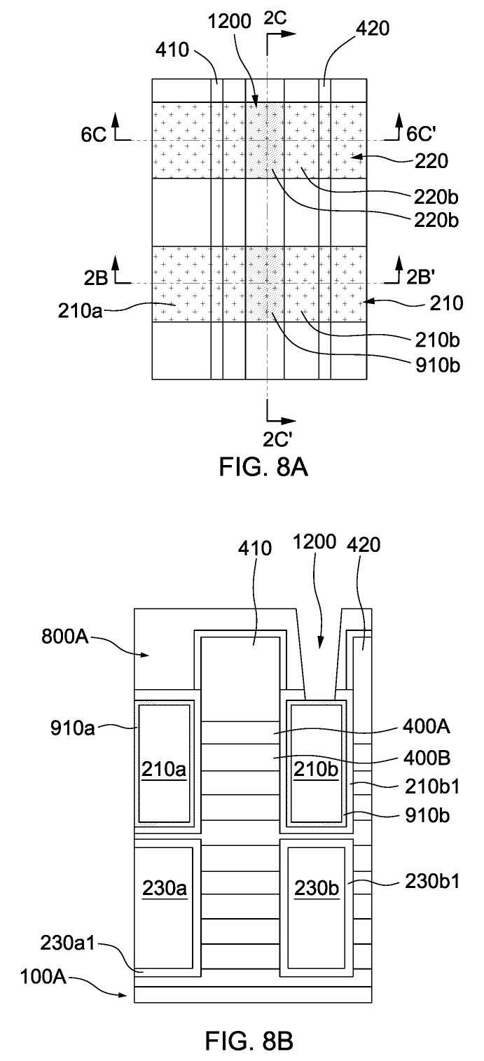

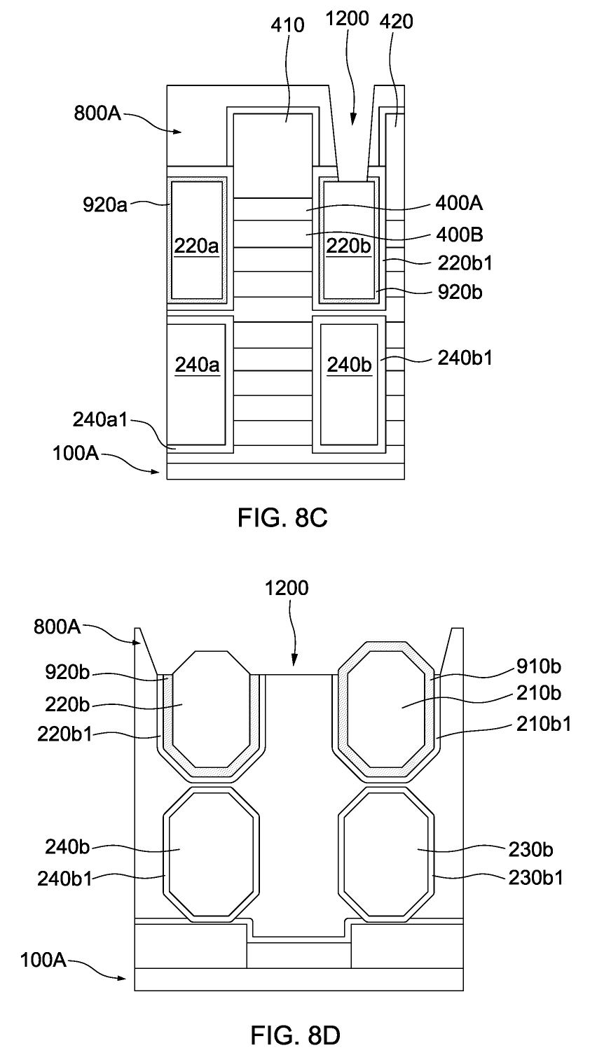

Referring to FIGS. 8A-8D, FIG. 8B illustrates a cross-sectional view along the cross-sectional line 2B-2B' in FIG. 8A, FIG. 8C illustrates a cross-sectional view along the cross-sectional line 6C-6C' in FIG. 8A, and FIG. 8D illustrates a cross-sectional view along the cross-sectional line 2C-2C' in FIG. 8A. In some embodiments, the protection layer 1300 is removed. In some embodiments, a portion of the conductive layer of the conductive segment 220b is exposed to the trench 1200, and the conductive layer of the conductive segment 210b remains entirely covered by the isolation layer 910b.

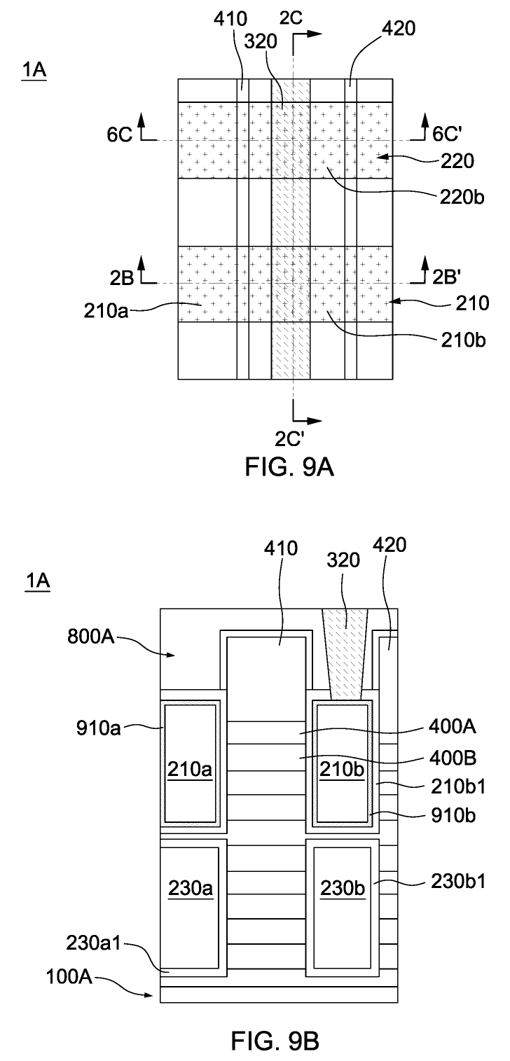

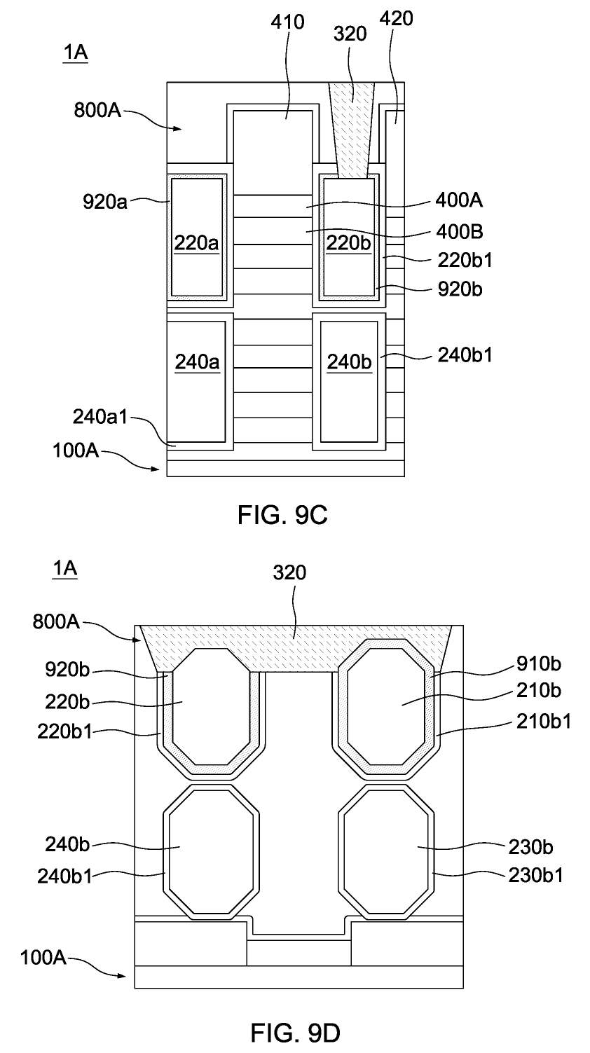

Referring to FIGS. 9A-9D, FIG. 9B illustrates a cross-sectional view along the cross-sectional line 2B-2B' in FIG. 9A, FIG. 9C illustrates a cross-sectional view along the cross-sectional line 6C-6C' in FIG. 9A, and FIG. 9D illustrates a cross-sectional view along the cross-sectional line 2C-2C' in FIG. 9A. In some embodiments, a conductive material is formed in the trench 1200 to form a contact 320 extending on the conductive segments 210b and 220b. The conductive material may be formed by deposition. As such, a semiconductor device 1A is formed.

In some embodiments, further referring to FIG. 1C, one or more dielectric materials may be formed over the contact 320 which together with the insulation structure 800A may form an insulation structure 800, a conductive via 713 may be formed passing the insulation structure 800 to electrically connect to the contact 320, and conductive traces 510, 512, 514, 516, 518, and 519 may be formed over the conductive segments 210b and 220b. Next, the as-formed structure may be flipped over by 180°, contacts 360 and 362 may be formed on the conductive segments 230b and 240b, conductive vias 723 and 724 may be formed to electrically connect to the contacts 360 and 362, and conductive traces 610, 612, 614, 616, 618, and 619 may be formed over the conductive segments 230b and 240b. As such, the structure illustrated in FIG. 1C may be formed.

In some embodiments, further referring to FIGS. 1A-1D, one or more operations which are the same or similar to those illustrated in FIGS. 2A-9D may be performed to form the semiconductor device 1.

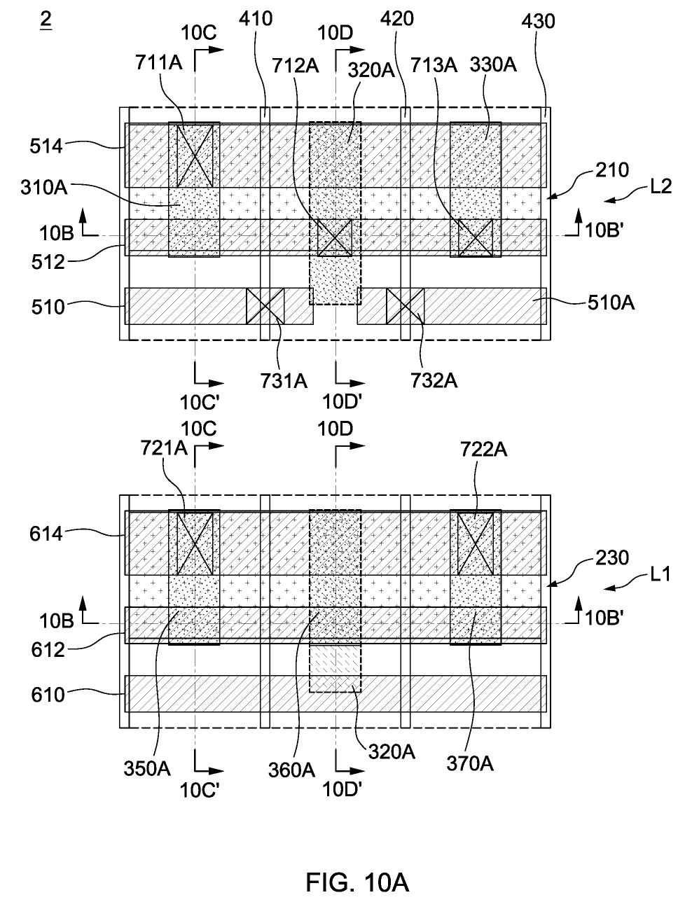

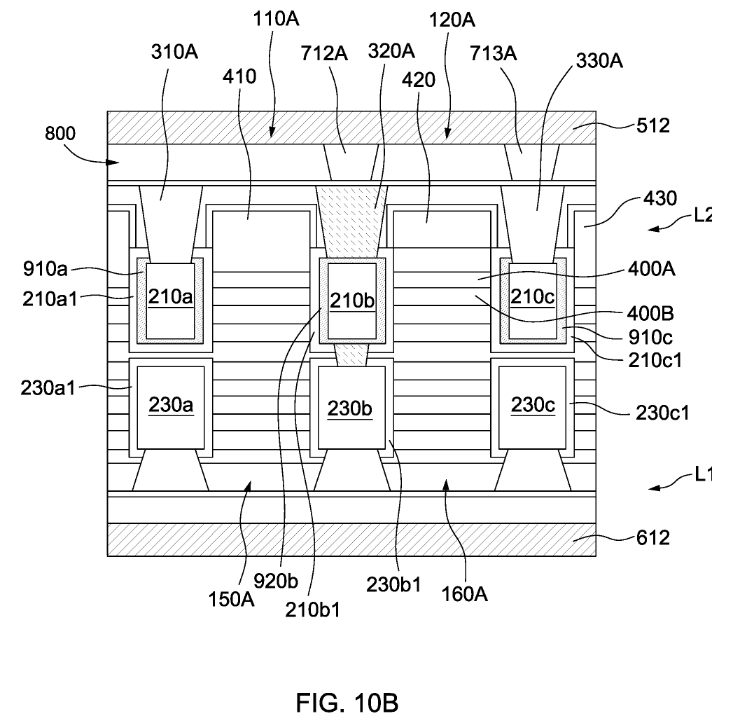

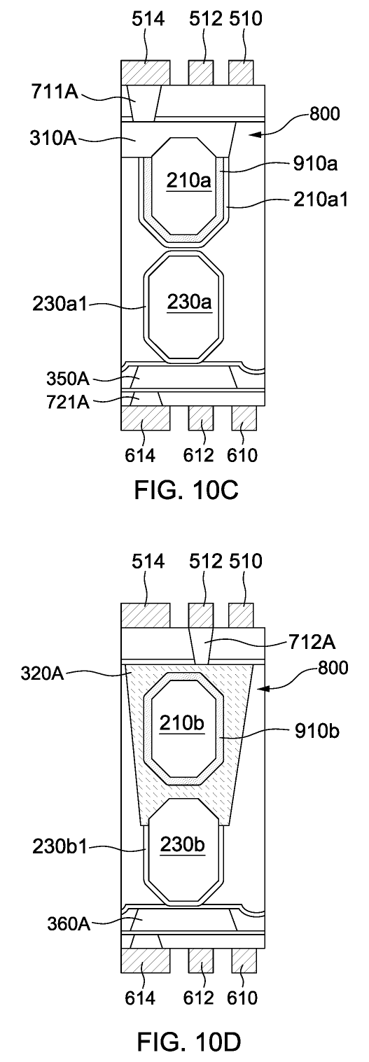

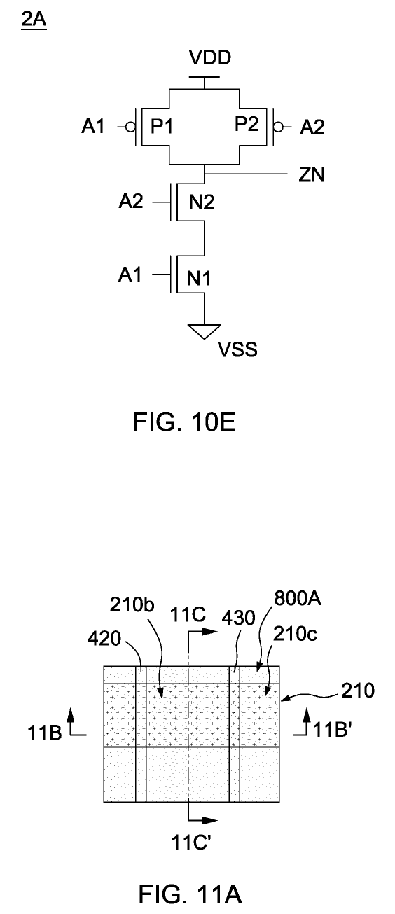

FIG. 10A is a top view of a semiconductor device 2 in accordance with some embodiments of the present disclosure. FIG. 10B is a cross-sectional view of a semiconductor device 2 in accordance with some embodiments of the present disclosure. FIG. 10C is a cross-sectional view of a semiconductor device 2 in accordance with some embodiments of the present disclosure. FIG. 10D is a cross-sectional view of a semiconductor device 2 in accordance with some embodiments of the present disclosure. In some embodiments, FIG. 10B illustrates a cross-sectional view along the cross-sectional line 10B-10B' in FIG. 10A, FIG. 10C illustrates a cross-sectional view along the cross-sectional line 10C-10C' in FIG. 10A, and FIG. 10D illustrates a cross-sectional view along the cross-sectional line 10D-10D' in FIG. 10A. In some embodiments, FIG. 10A illustrates a top view of a lower layer L1 and a top view of an upper layer L2 of the semiconductor device 2. In some embodiments, the semiconductor device 2 is similar to the semiconductor device 1 in FIGS. 1A-1D, with differences therebetween as follows. Descriptions of similar components are omitted.

Referring to FIGS. 10A-10D, the semiconductor device 2 may be a portion of a standard cell. The semiconductor device 2 may include at least transistors 110A, 120A, 150A, and 160A. In some embodiments, the transistors 110A and 120A are stacked over the transistors 150A and 160A. The transistors 110A and 120A may have the same conductivity type, and the transistors 150A and 160A may have the same conductivity type. The transistors at the lower layer L1 and the transistors at the upper layer L2 may have opposite conductivity types. In some embodiments, the transistors 110A and 120A are n-type transistors, and the transistors 150A and 160A are p-type transistors, and vice versa.

Referring to FIGS. 10A-10D, the layout structure of the semiconductor device 2 may include active regions 210 and 230, contacts 310A, 320A, 330A, 350A, 360A, and 370A (also referred to as "source/drain (S/D) contacts"), gates 410, 420, and 430, and stacked channel structures each including nanosheet channels 400A and 400B. Each of the active regions may include conductive segments (e.g., epitaxial structures). The conductive segments of the active regions may serve as source/drains (S/Ds) of the transistors. In some embodiments, the transistor 110A includes the gate 410 and the conductive segments 210a and 210b on opposite sides of the gate 410. In some embodiments, the transistor 120A includes the gate 420 and the conductive segments 210b and 210c on opposite sides of the gate 420. In some embodiments, the transistor 150A includes the gate 410 and the conductive segments 230a and 230b on opposite sides of the gate 410. In some embodiments, the transistor 160A includes the gate 420 and the conductive segments 230b and 230c on opposite sides of the gate 420. In some embodiments, the gate 430 is a dummy gate. In some other embodiments, the gate 430 is a functional gate of a device adjacent to the cell of the semiconductor device 2. In some embodiments, each stack of the nanosheet channels 400A and 400B is between adjacent conductive segments at the upper layer L2 and between adjacent conductive segments the lower layer L1.

Referring to FIGS. 10A-10D, the layout structure of the semiconductor device 2 may further include conductive traces 510, 510A, 512, 514, 610, 612, and 614, conductive vias 711A, 712A, 713A, 721A, 722A, 731A, and 732A, and an insulation structure 800. In some embodiments, the conductive vias 711A, 712A, and 713A serve to electrically connect the S/D contacts (e.g., the contacts 310A, 320A, and 330A) at the upper layer L2 to the conductive traces over the upper layer L2. In some embodiments, the conductive vias 721A and 722A serve to electrically connect the S/D contacts (e.g., the contacts 350A, 360A, and 370A) at the lower layer L1 to the conductive traces under the lower layer L1. In some embodiments, the conductive vias 731A and 732A serve to electrically connect the gates to the conductive traces over the upper layer L2.

Referring to FIGS. 10A-10D, the layout structure of the semiconductor device 2 may further include at least isolation layers 910a, 910b, and 910c. In some embodiments, each of the isolation layers covers a corresponding conductive segment at the upper layer L2. For example, the isolation layer 910a may cover the conductive segment 210a, the isolation layer 910b may cover the conductive segment 210b, and the isolation layer 910c may cover the conductive segment 210c.

Referring to FIGS. 10A-10D, in some embodiments, the contact 320A covers and is electrically isolated from the conductive segment (or the S/D) 210b of the transistor 110A, and the contact 320A is electrically connected to the transistor 120A. In some embodiments, the contact 320A is electrically connected to the conductive segment (or the S/D) 210c of the transistor 120A through the conductive via 712A, the conductive trace 520, and the conductive via 713A. In some embodiments, the isolation layer 920b covers a circumferential surface of the conductive segment 210b and electrically isolates the contact 320A from the conductive segment 210b. In some embodiments, the isolation layer 920b is between and directly contacts the contact 320A and the conductive segment (or the S/D) 210b of the transistor 110A. In some embodiments, the contact 320A covers or contacts a circumferential surface of the isolation layer 920b.

Referring to FIGS. 10A-10D, in some embodiments, the contact 320A is electrically connected to transistor 150A. In some embodiments, the contact 320A further covers the conductive segment (or the S/D) 230b of the transistor 150A. In some embodiments, the conductive segment 230a is directly under the conductive segment 210a, and the conductive segment 230b is directly under the conductive segment 210b. In some embodiments, the contact 320A is electrically connected to the conductive segment (or the S/D) 230b of the transistor 150A. In some embodiments, the transistor 150A is offset from the transistor 120 from a top view perspective, and the transistor 150A is electrically connected to the transistor 120 through the contact 320A. In some embodiments, the conductive segment (or the S/D) 230b of the transistor 150A is electrically connected to the conductive segment (or the S/D) 210c of the transistor 120 through the contact 320A, the conductive via 712A, the conductive trace 510A, and the conductive via 713A.

In some embodiments, the spacer layer 230b1 has an opening exposing a portion of the conductive segment 230b which contacts and electrically connects to the contact 320A. In some embodiments, the contact 320A directly contacts a portion of the conductive segment 230b of the transistor 150A. In some embodiments, the contact 320A include a portion conformally formed on the conductive segment 230b of the transistor 150A. In some embodiments, the contact 320A includes an extension between the transistor 110A and the transistor 150A.

In some embodiments, the conductive segment 210b is an internal common S/D or a shared S/D between different transistors. In some embodiments, the transistor 110A and the transistor 120A share the conductive segment 210b as a shared S/D. In some embodiments, the isolation layer 920b covers the conductive segment 210b (or the shared S/D), and the conductive segment 210b (or the shared S/D) is electrically isolated from an external connector. That is, there is not external connector electrically connected to the conductive segment 210b.

The structure in FIGS. 10A-10D may be applied to various integrated circuits/circuit cells to increasing routing flexibility. FIG. 10E illustrates a schematic view of a circuit 2A in accordance with some embodiments of the present disclosure. In some embodiments, the circuit 2A illustrated in FIG. 10E may be implemented with the semiconductor device 2 illustrated in FIGS. 10A-10D. In some embodiments, the circuit 2A is an ND2D1 (NAND 2-input) circuit and includes NMOS transistors N1 and N2 and PMOS transistors P1 and P2. The source terminal of the NMOS transistor N1 is coupled to a VSS signal, the gate terminal of the NMOS transistor N1 is coupled to an input signal A1, and the drain terminal of the NMOS transistor N1 is coupled the source terminal of the NMOS transistor N2. The gate terminal of the NMOS transistor N2 is coupled to an input signal A2, and the source terminal of the NMOS transistor N2 is couple to a signal Zn and the drain terminals of the PMOS transistors P1 and P2. The source terminals of the PMOS transistors P1 and P2 are coupled to a VDD signal, and the gate terminals of the PMOS transistors P1 and P2 are respectively coupled to the input terminal A1 and the input terminal A2.

Referring to FIGS. 10A-10E, the transistor N1 may correspond to the transistor 110A, the transistor N2 may correspond to the transistor 120A, and the transistor P1 and P2 may correspond to the transistors 150A and 160A. In some embodiments, the conductive trace 514 is electrically connected to the VSS signal and electrically connected to the contact 310A through the conductive via 711A. In some embodiments, the conductive trace 614 is electrically connected to the VDD signal and electrically connected to the contact 350A and the contact 370A through the conductive via 721A and the conductive via 722A, respectively. In some embodiments, the conductive trace 510 is electrically connected to the input signal A1, and the conductive trace 510A is electrically connected to the input signal A2. In some embodiments, the conductive segment 210c of the transistor 120A (i.e., the drain of the NMOS transistor 120A) is electrically connected to the conductive segment 230c of the transistor 150A and the transistor 160A (i.e., the common drain of the PMOS transistors 150A and 160A) through the conductive trace 512.

According to some embodiments of the present disclosure, with the aforesaid design, the contact 320A can extend over the conductive segment 210b to further electrically connect to conductive features in other transistors without arranging additional stacked conductive traces or vias. For example, the contact 320A can serve to electrically connect conductive features of two transistors that are across over one or more gates or at different elevations (e.g., at the upper layer L2 and the lower layer L1). Therefore, the routing flexibility can be increased, and the number of layers of conductive traces can be reduced.

In addition, according to some embodiments of the present disclosure, the contact 320A passes over without electrically connecting to the conductive segment 210b at the upper layer L2 and extends downwards to contact the conductive segment 230b stacked under the conductive segment 210b, and the contact 320A at the upper layer L2 can further electrically connect to other conductive features at the upper layer L2 through the conductive trace 510. Thus, vertical electrical connection between conductive features at different elevations or layers can be achieved without forming deep vias between conductive traces over the upper layer L2 and below the lower layer L1. Therefore, the risk of forming deep vias, e.g., reduced yields resulted from the relatively high aspect ratios of deep vias, relatively high resistance caused by the relatively long electrical paths provided by the deep vias, and etc., can be mitigated or prevented. Accordingly, the yields can be increased, and the structure stability and reliability of the semiconductor device 2 can be improved.

Moreover, according to some embodiments of the present disclosure, the contact 320A and other S/D contacts may be formed in the same operations, and/or the contact 320A may be disposed at the position preserved for S/D contacts. Furthermore, the vertical electrical connection mechanism can be realized by the contact 320A and existing conductive features, such as conductive traces (also referred to as "metal layer M0") and conductive vias between the S/D contacts and the conductive traces, no extra layers or volumes for additional conductive structures are required. Therefore, the device area or volume is not increased due to the formation of the vertical electrical connection mechanism (e.g., the contact 320A), which is advantageous to the reduction of device areas and sizes.

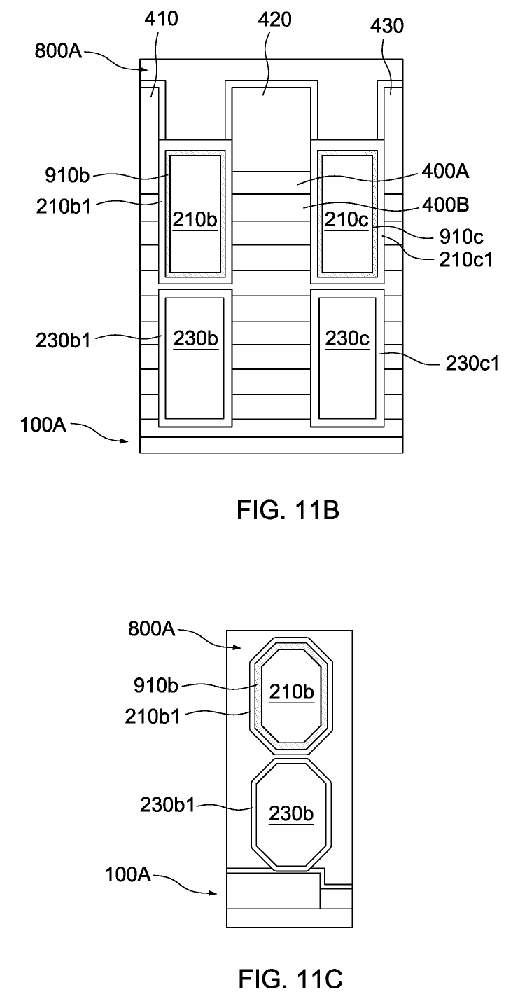

FIGS. 11A to 14C are schematic views of intermediate stages of a method of manufacturing a semiconductor device 2 in accordance with some embodiments of the present disclosure.

Referring to FIGS. 11A-11C, FIG. 11B illustrates a cross-sectional view along the cross-sectional line 11B-11B' in FIG. 11A, and FIG. 11C illustrates a cross-sectional view along the cross-sectional line 11C-11C' in FIG. 11A. In some embodiments, stacks of nanosheet channels 400A and 400B are formed over a substrate 100A, conductive segments 230b and 230c are formed on opposite sides of a stack of nanosheet channels 400A and 400B, and conductive segments 210b and 210c are formed over the conductive segments 230b and 230c and on opposite sides of the stack of nanosheet channels 400A and 400B. In some embodiments, gates 420 and 430 are formed on the stacks of nanosheet channels 400A and 400B, and an insulation structure 800A is formed covering the conductive segments 210b, 210c, 230b, and 230c, the nanosheet channels 400A and 400B, and the gates 420 and 430. In some embodiments, the insulation structure 800A includes an oxide layer, and the substrate 100A may include a silicon layer over a buried oxide layer.

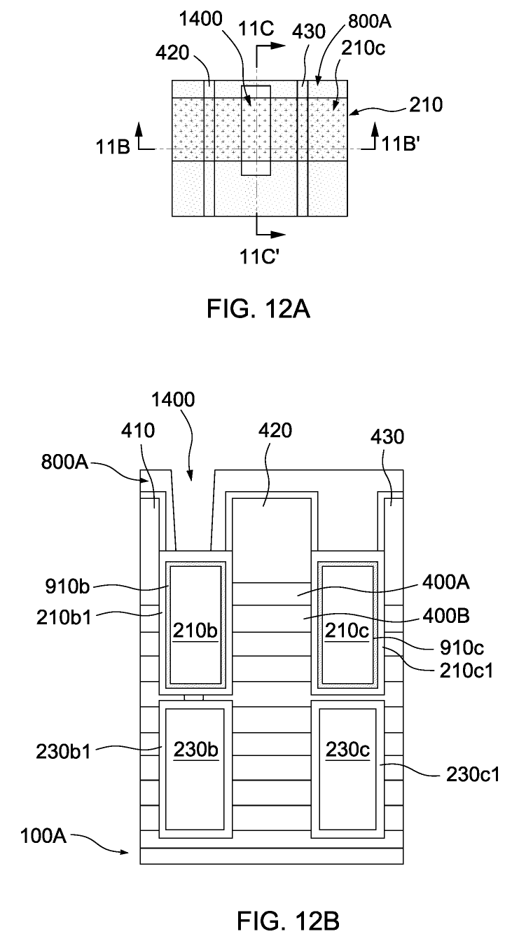

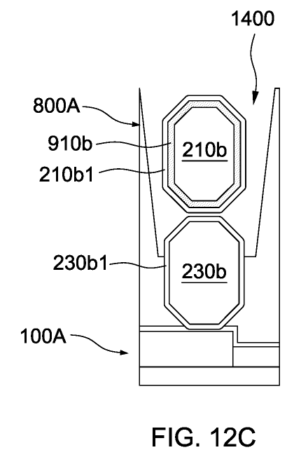

Referring to FIGS. 12A-12C, FIG. 12B illustrates a cross-sectional view along the cross-sectional line 11B-11B' in FIG. 12A, and FIG. 12C illustrates a cross-sectional view along the cross-sectional line 11C-11C' in FIG. 12A. In some embodiments, a trench 1400 may be formed in and passing through the insulation structure 800A. In some embodiments, the spacer layers 210b1 and 230b1 are exposed to the trench 1400. In some embodiments, the trench 1400 surrounds the conductive segment 210b and is spaced apart from the conductive segment 210b by the isolation layer 910b and the spacer layer 210b1. In some embodiments, a circumferential surface of the spacer layer 210b1 is exposed to the trench 1400. The trench 1400 may be formed by etching.

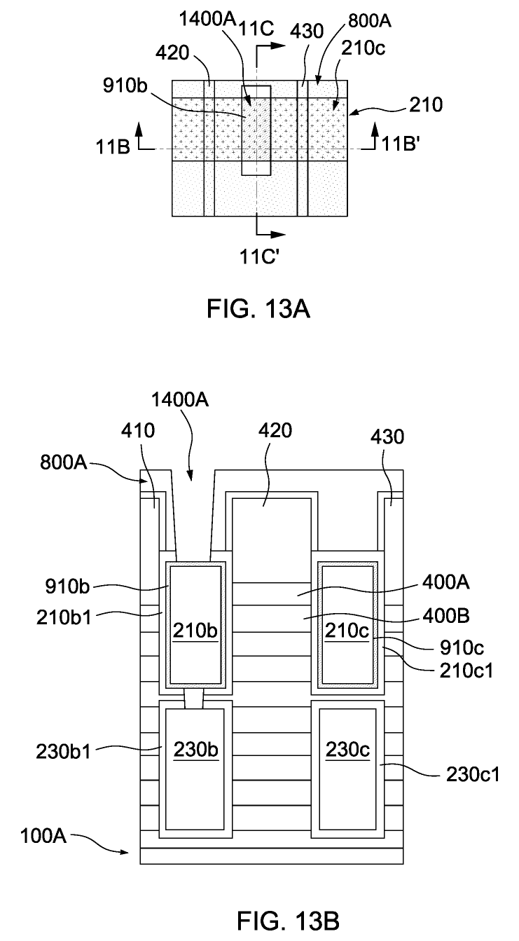

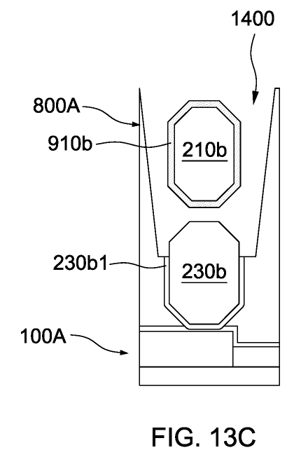

Referring to FIGS. 13A-13C, FIG. 13B illustrates a cross-sectional view along the cross-sectional line 11B-11B' in FIG. 13A, and FIG. 13C illustrates a cross-sectional view along the cross-sectional line 11C-11C' in FIG. 13A. In some embodiments, a portion of the spacer layer 210b1 and a portion of the spacer layer 230b1 exposed to the trench 1400 may be removed to form a trench 1400A. In some embodiments, a portion of the isolation layer 910b and a portion of the conductive layer of the conductive segment 230b are exposed to the trench 1400A. In some embodiments, the trench 1400A surrounds the conductive segment 210b and is spaced apart from the conductive segment 210b by the isolation layer 910b. In some embodiments, a circumferential surface of the isolation layer 910b is exposed to the trench 1400A. The removal operation may be formed by etching.

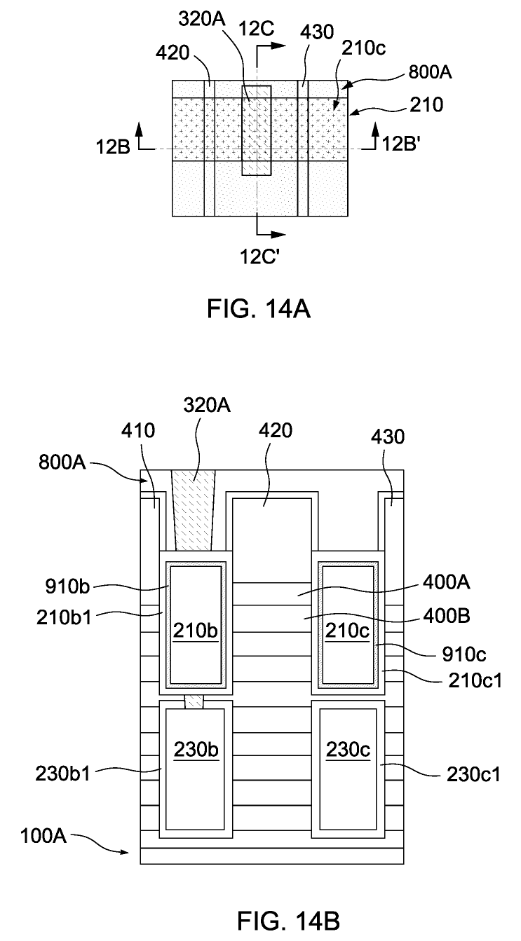

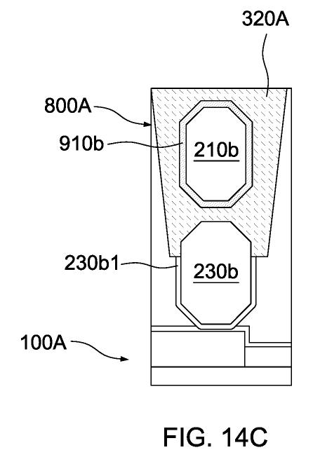

Referring to FIGS. 14A-14C, FIG. 14B illustrates a cross-sectional view along the cross-sectional line 11B-11B' in FIG. 14A, and FIG. 14C illustrates a cross-sectional view along the cross-sectional line 11C-11C' in FIG. 14A. In some embodiments, a conductive material is formed in the trench 1400A to form a contact 320A contacting the isolation layer 910b and a portion of the conductive segment 230b. The conductive material may be formed by deposition. As such, a semiconductor device 2B is formed.

In some embodiments, further referring to FIGS. 10A-10D, one or more operations which are the same or similar to those illustrated in FIGS. 11A-14C may be performed to form the semiconductor device 2.

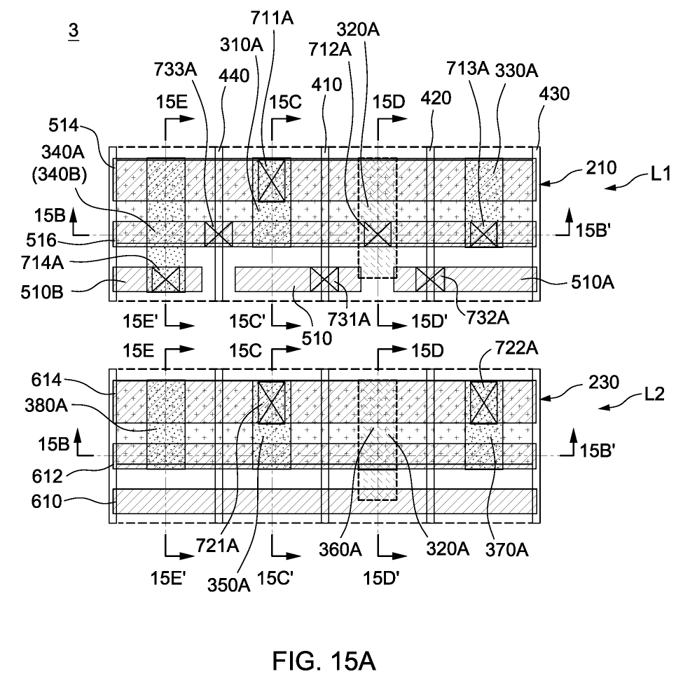

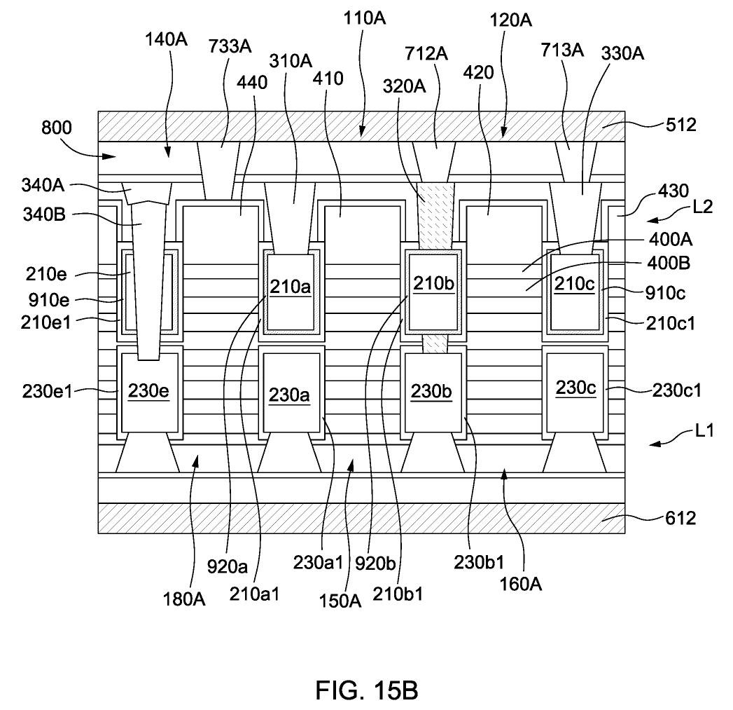

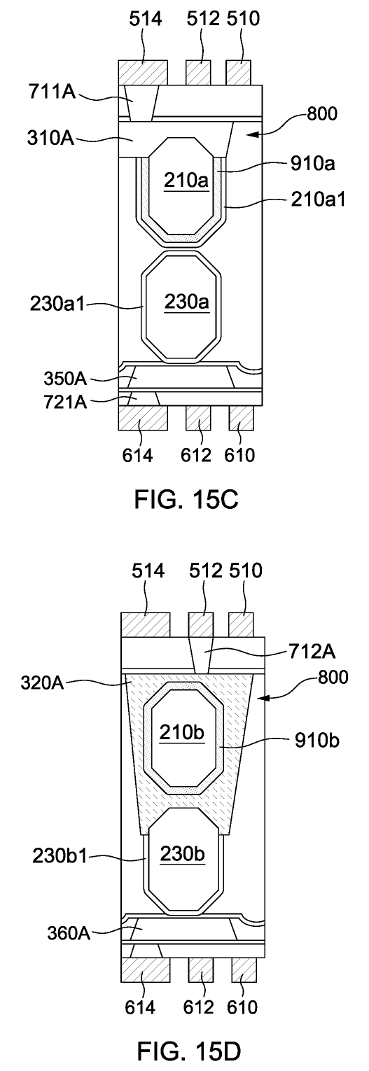

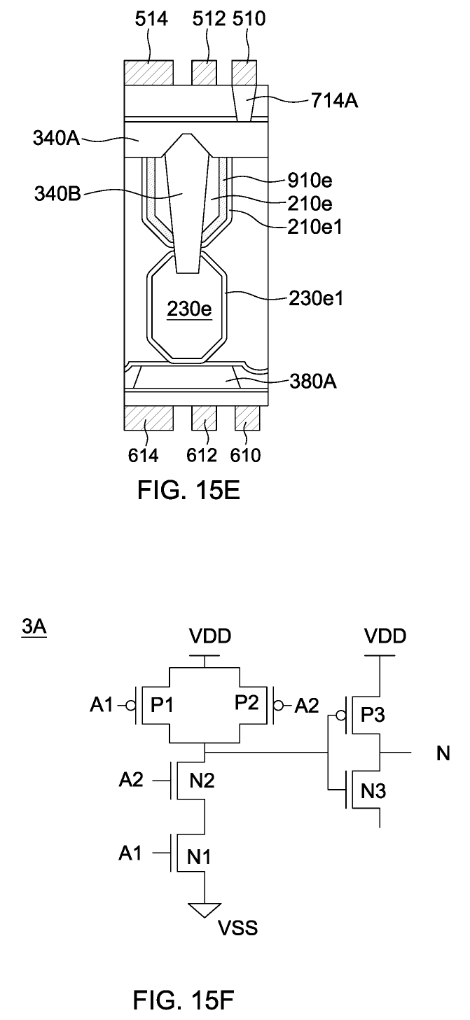

FIG. 15A is a top view of a semiconductor device 3 in accordance with some embodiments of the present disclosure. FIG. 15B is a cross-sectional view of a semiconductor device 3 in accordance with some embodiments of the present disclosure. FIG. 15C is a cross-sectional view of a semiconductor device 3 in accordance with some embodiments of the present disclosure. FIG. 15D is a cross-sectional view of a semiconductor device 3 in accordance with some embodiments of the present disclosure. FIG. 15E is a cross-sectional view of a semiconductor device 3 in accordance with some embodiments of the present disclosure. In some embodiments, FIG. 15B illustrates a cross-sectional view along the cross-sectional line 15B-15B' in FIG. 15A, FIG. 15C illustrates a cross-sectional view along the cross-sectional line 15C-15C' in FIG. 15A, FIG. 15D illustrates a cross-sectional view along the cross-sectional line 15D-15D' in FIG. 15A, and FIG. 15E illustrates a cross-sectional view along the cross-sectional line 15E-15E' in FIG. 15A. In some embodiments, FIG. 15A illustrates a top view of a lower layer L1 and a top view of an upper layer L2 of the semiconductor device 3. In some embodiments, the semiconductor device 3 is similar to the semiconductor device 2 in FIGS. 10A-10D, with differences therebetween as follows. Descriptions of similar components are omitted.

Referring to FIGS. 15A-15E, the semiconductor device 3 may be a portion of a standard cell. The semiconductor device 3 may include at least transistors 110A, 120A, 140A, 150A, 160A, and 180A. The transistors 110A, 120A, and 140A may have the same conductivity type, and the transistors 150A, 160A, and 180A may have the same conductivity type. In some embodiments, the transistors 110A, 120A, and 140A are n-type transistors, and the transistors 150A, 160A, and 180A are p-type transistors, and vice versa.

Referring to FIGS. 15A-15E, the layout structure of the semiconductor device 3 may include active regions 210 and 230, contacts 310A, 320A, 330A, 340A, 340B, 350A, 360A, 370A, and 380A (also referred to as "source/drain (S/D) contacts"), gates 410, 420, 430, and 440, and stacked channel structures each including nanosheet channels 400A and 400B. Each of the active regions may include conductive segments (e.g., epitaxial structures). The conductive segments of the active regions may serve as source/drains (S/Ds) of the transistors. In some embodiments, the transistor 140A includes the gate 440 and the conductive segments 210a and 210e on opposite sides of the gate 440. In some embodiments, the transistor 180A includes the gate 440 and the conductive segments 230a and 230e on opposite sides of the gate 440.

Referring to FIGS. 15A-15E, the layout structure of the semiconductor device 3 may further include a conductive trace 510B, conductive vias 714A and 733A, and an isolation layer 910e. In some embodiments, the gate 440 is electrically connected to the trace 510 through the conductive via 733A. In some embodiments, the contact 340A is electrically connected to the conductive trace 510B through the conductive via 714A. In some embodiments, the contact 340B penetrates and electrically connects the conductive segment 210e and the conductive segment 230e. In some embodiments, the contact 340B penetrates the isolation layer 910e and the spacer layers 210e1 and 230e1 to electrically connect the conductive segment 230e, the conductive segment 210e, and the contact 340A.

The structure in FIGS. 15A-15E may be applied to various integrated circuits/circuit cells to increasing routing flexibility. FIG. 15F illustrates a schematic view of a circuit 3A in accordance with some embodiments of the present disclosure. In some embodiments, the circuit 3A illustrated in FIG. 15F may be implemented with the semiconductor device 3 illustrated in FIGS. 15A-15E. In some embodiments, the circuit 3A is an AN2D1 circuit and includes NMOS transistors N1, N2, and N3 and PMOS transistors P1, P2, and P3. The gate terminal of the transistor N1 is coupled to the gate terminal of the transistor P1 and an input signal A1, the source terminal of the transistor N1 is coupled to the drain terminals of the transistors P1 and P2 and the gate terminals of the transistors N3 and P3, and the drain terminal of the transistor N1 is coupled to the source terminal of the transistor N2. The gate terminal of the transistor N2 is coupled to the gate terminal of the transistor P2 and an input signal A2, and the drain terminal of the transistor N2 is coupled to the drain terminal of the transistor N3 and a VSS signal. The source terminal of the transistor N3 is coupled to the drain terminals of the transistor P3 and a signal Z. The source terminal of the transistor P1 is coupled to a VDD signal. The source terminal of the transistor P2 is coupled to the source terminal of the transistor P3 and the VDD signal.

Referring to FIGS. 15A-15F, the transistor N1 may correspond to the transistor 110A, the transistor N2 may correspond to the transistor 120A, the transistor N3 may correspond to the transistor 140A, the transistor P1 and P2 may correspond to the transistors 150A and 160A, and the transistor P3 may correspond to the transistor 180A. In some embodiments, the gate 440 (i.e., the gate terminals of the transistors 140A and 180A) is connected to the conductive segment 210c of the transistor 120A (i.e., the drain of the NMOS transistor 120A) and the conductive segment 230c of the transistor 150A and the transistor 160A (i.e., the common drain of the PMOS transistors 150A and 160A) through the conductive trace 512.

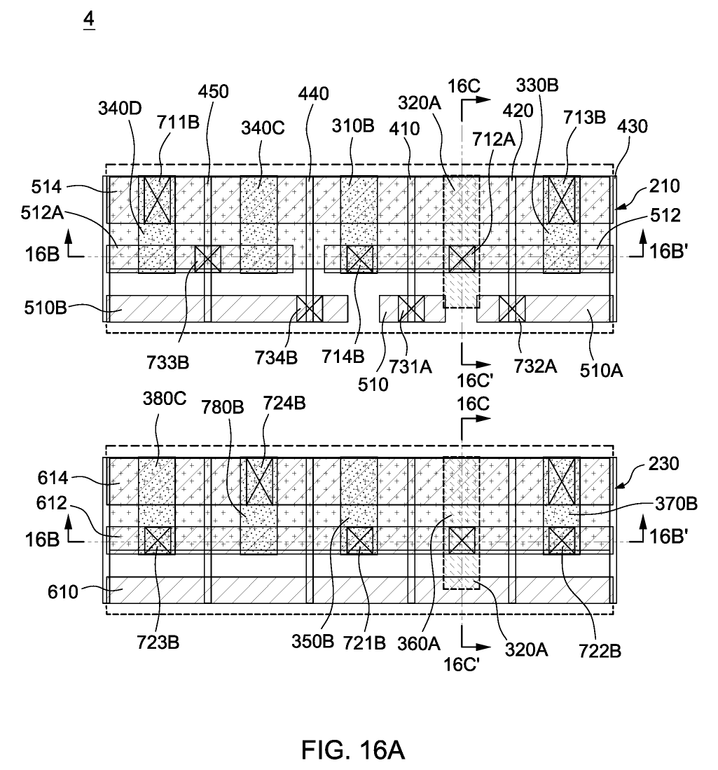

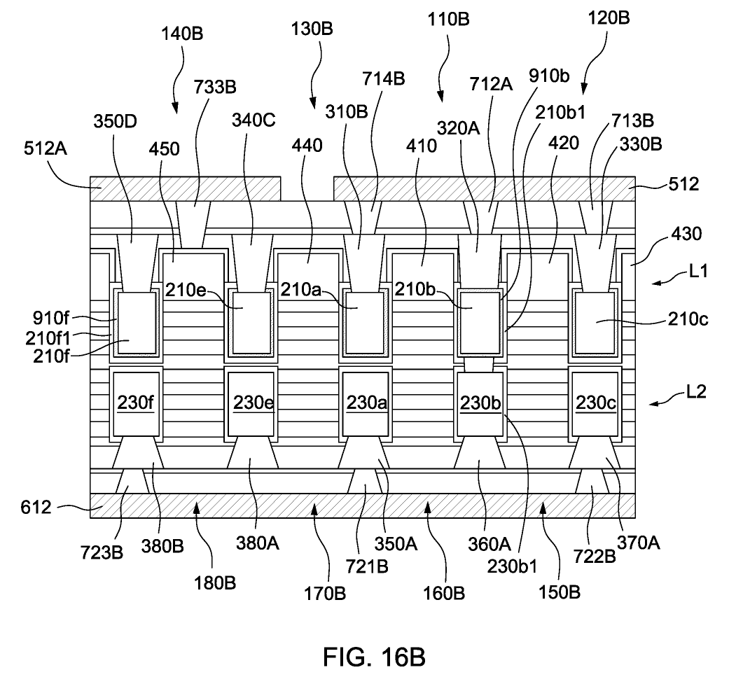

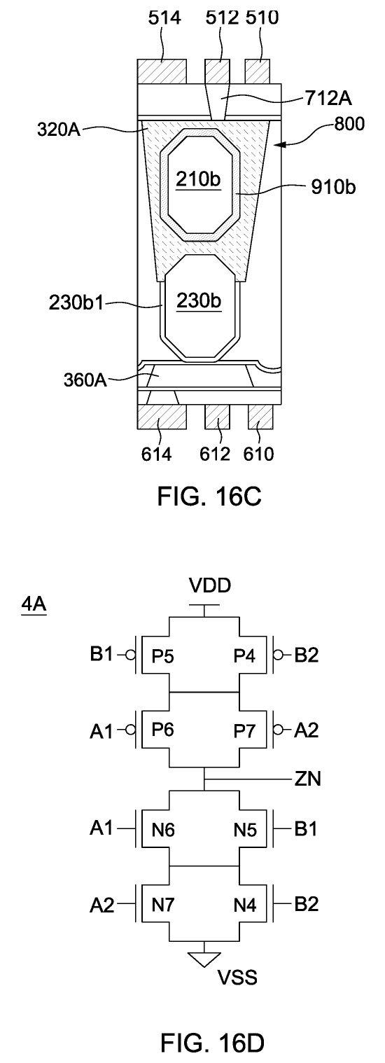

FIG. 16A is a top view of a semiconductor device 4 in accordance with some embodiments of the present disclosure. FIG. 16B is a cross-sectional view of a semiconductor device 4 in accordance with some embodiments of the present disclosure. FIG. 16C is a cross-sectional view of a semiconductor device 4 in accordance with some embodiments of the present disclosure. In some embodiments, FIG. 16B illustrates a cross-sectional view along the cross-sectional line 16B-16B' in FIG. 16A, and FIG. 16C illustrates a cross-sectional view along the cross-sectional line 16C-16C' in FIG. 16A. In some embodiments, FIG. 16A illustrates a top view of a lower layer L1 and a top view of an upper layer L2 of the semiconductor device 4. In some embodiments, the semiconductor device 4 is similar to the semiconductor device 2 in FIGS. 10A-10D, with differences therebetween as follows. Descriptions of similar components are omitted.

Referring to FIGS. 16A-16C, the semiconductor device 4 may be a portion of a standard cell. The semiconductor device 2 may include at least transistors 110B, 120B, 130B, 140B, 150B, 160B, 170B, and 180B. In some embodiments, the transistors 110B, 120B, 130B, and 140B are stacked over the transistors 150B, 160B, 170B, and 180B. The transistors 110B, 120B, 130B, and 140B may have the same conductivity type, and the transistors 150B, 160B, 170B, and 180B may have the same conductivity type. The transistors at the lower layer L1 and the transistors at the upper layer L2 may have opposite conductivity types. In some embodiments, the transistors 110B, 120B, 130B, and 140B are n-type transistors, and the transistors 150B, 160B, 170B, and 180B are p-type transistors, and vice versa.

Referring to FIGS. 16A-16C, the layout structure of the semiconductor device 2 may include active regions 210 and 230, contacts 310B, 320A, 330B, 340C, 340D, 350B, 360B, 370B, and 380B (also referred to as "source/drain (S/D) contacts"), gates 410, 420, 430, 440, and 450, and stacked channel structures each including nanosheet channels 400A and 400B. Each of the active regions may include conductive segments (e.g., epitaxial structures). The conductive segments of the active regions may serve as source/drains (S/Ds) of the transistors. In some embodiments, the transistor 110B includes the gate 410 and the conductive segments 210a and 210b on opposite sides of the gate 410. In some embodiments, the transistor 120B includes the gate 420 and the conductive segments 210b and 210c on opposite sides of the gate 420. In some embodiments, the transistor 130B includes the gate 440 and the conductive segments 210a and 210e on opposite sides of the gate 440. In some embodiments, the transistor 140B includes the gate 450 and the conductive segments 210e and 210f on opposite sides of the gate 450. In some embodiments, the transistor 150B includes the gate 410 and the conductive segments 230a and 230b on opposite sides of the gate 410. In some embodiments, the transistor 160B includes the gate 420 and the conductive segments 230b and 230c on opposite sides of the gate 420. In some embodiments, the transistor 170B includes the gate 440 and the conductive segments 230a and 230e on opposite sides of the gate 440. In some embodiments, the transistor 180B includes the gate 450 and the conductive segments 230e and 230f on opposite sides of the gate 450. In some embodiments, each stack of the nanosheet channels 400A and 400B is between adjacent conductive segments at the upper layer L2 and between adjacent conductive segments the lower layer L1.

Referring to FIGS. 16A-16C, the layout structure of the semiconductor device 4 may further include conductive traces 510, 510A, 510B, 512, 512A, 514, 610, 612, and 614, conductive vias 711B, 712A, 713B, 714B, 721B, 722B, 723B, 724B, 731A, 732A, 733B, and 734B, and an insulation structure 800. In some embodiments, the conductive vias 711B, 712A, 713B, and 714B serve to electrically connect the S/D contacts (e.g., the contacts 310B, 320A, 330B, 340C, and 340D) at the upper layer L2 to the conductive traces over the upper layer L2. In some embodiments, the conductive vias 721B, 722B, 723B, and 724B serve to electrically connect the S/D contacts (e.g., the contacts 350B, 360B, 370B, and 380B) at the lower layer L1 to the conductive traces under the lower layer L1. In some embodiments, the conductive vias 731A, 732A, 733B, and 734B serve to electrically connect the gates to the conductive traces over the upper layer L2.

Referring to FIGS. 16A-16C, the layout structure of the semiconductor device 4 may further include at least isolation layers 910a, 910b, 910c, 910e, and 910f. In some embodiments, each of the isolation layers covers a corresponding conductive segment at the upper layer L2. For example, the isolation layer 910a may cover the conductive segment 210a, the isolation layer 910b may cover the conductive segment 210b, the isolation layer 910c may cover the conductive segment 210c, the isolation layer 910e may cover the conductive segment 210e, and the isolation layer 910f may cover the conductive segment 210f.

Referring to FIGS. 16A-16C, in some embodiments, the contact 320A covers and is electrically isolated from the conductive segment (or the S/D) 210b of the transistor 110B, and the contact 320A is electrically connected to the conductive segment 230b. In some embodiments, the contact 320A is electrically connected to the transistors 110B, 130B, 150B, and 160B. In some embodiments, the contact 320A is electrically connected to the conductive segment 210a (or the S/D) of the transistors 110B and 130B. In some embodiments, the contact 320A is electrically connected to the conductive segment 210a through the contact 310B, the conductive via 714B, the conductive trace 512, and the conductive via 712A. In some embodiments, the contact 320A electrically connects the transistors 110B and 130B to the transistors 150B and 160B. In some embodiments, the isolation layer 920b covers a circumferential surface of the conductive segment 210b and electrically isolates the contact 320A from the conductive segment 210b. In some embodiments, the isolation layer 920b is between and directly contacts the contact 320A and the conductive segment (or the S/D) 210b of the transistor 110B. In some embodiments, the contact 320A covers or contacts a circumferential surface of the isolation layer 920b.

In some embodiments, the conductive segment 210b is an internal common S/D or a shared S/D between different transistors. In some embodiments, the transistor 110B and the transistor 120B share the conductive segment 210b as a shared S/D. In some embodiments, the isolation layer 920b covers the conductive segment 210b (or the shared S/D), and the conductive segment 210b (or the shared S/D) is electrically isolated from an external connector. That is, there is not external connector electrically connected to the conductive segment 210b.

The structure in FIGS. 16A-16C may be applied to various integrated circuits/circuit cells to increasing routing flexibility. FIG. 16D illustrates a schematic view of a circuit 4A in accordance with some embodiments of the present disclosure. In some embodiments, the circuit 4A illustrated in FIG. 16D may be implemented with the semiconductor device 4 illustrated in FIGS. 16A-16C. In some embodiments, the circuit 4A is an AOI22D1 circuit and includes NMOS transistors N4, N5, N6, and N7 and PMOS transistors P4, P5, P6, and P7. The gate terminal of the transistor N4 is coupled to the gate terminal of the transistor P4 and an input signal B2, the source terminal of the transistor N4 is coupled to the drain terminals of the transistor N5, and the drain terminal of the transistor N4 is coupled to a VSS signal. The gate terminal of the transistor N5 is coupled to the gate terminal of the transistor P5 and an input signal B1, and the source terminal of the transistor N5 is coupled to the drain terminals of the transistors P6 and P7, the source terminal of the transistor N6, and a ZN signal. The gate terminal of the transistor N6 is coupled to the gate terminal of the transistor P6 and an input signal A1, and the drain terminal of the transistor N6 is coupled to the source terminal of the transistor N7. The gate terminal of the transistor N7 is coupled to the gate terminal of the transistor P7 and an input signal A2, and the drain terminal of the transistor N7 is coupled to the VSS signal. The source terminal of the transistor P4 is coupled to a VDD signal and the source terminal of the transistor P5, and the drain terminal of the transistor P4 is coupled to the drain terminal of the transistor P5 and the source terminals of the transistors P6 and P7.

Referring to FIGS. 16A-16D, the transistor N4 may correspond to the transistor 120B, the transistor N5 may correspond to the transistor 110B, the transistor N6 may correspond to the transistor 130B, the transistor N7 may correspond to the transistor 140B, the transistor P4 and P5 may correspond to the transistors 170B and 180B, and the transistor P6 and P7 may correspond to the transistors 150B and 160B. In some embodiments, the conductive trace 514 is electrically connected to the VSS signal and electrically connected to the contact 340D and the contact 330B through the conductive via 711B and the conductive via 731B, respectively. In some embodiments, the conductive trace 614 is electrically connected to the VDD signal and electrically connected to the contact 380B through the conductive via 724B. In some embodiments, the conductive trace 510 is electrically connected to the input signal A1, and the conductive trace 510A is electrically connected to the input signal A2. In some embodiments, the conductive segment 230b (the shared drain of the transistors 150B and 160B) is electrically connected to the conductive segment 210a (the shared drain of the transistors 110B and 130B) through the contact 320A, the conductive via 712A, the conductive trace 512, the conductive via 714B, and the contact 310B.

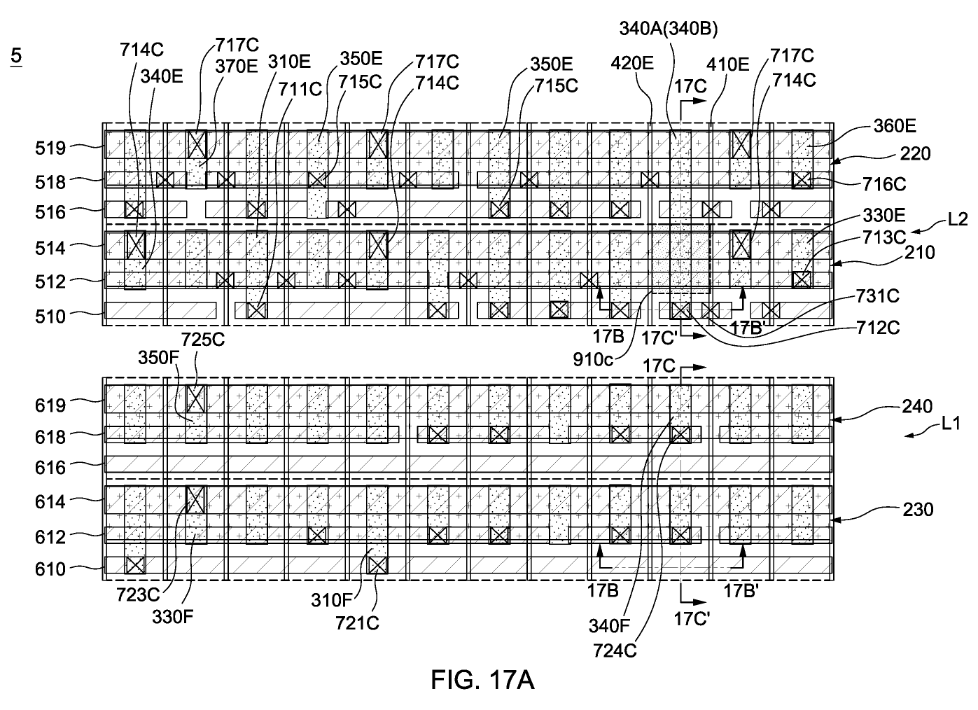

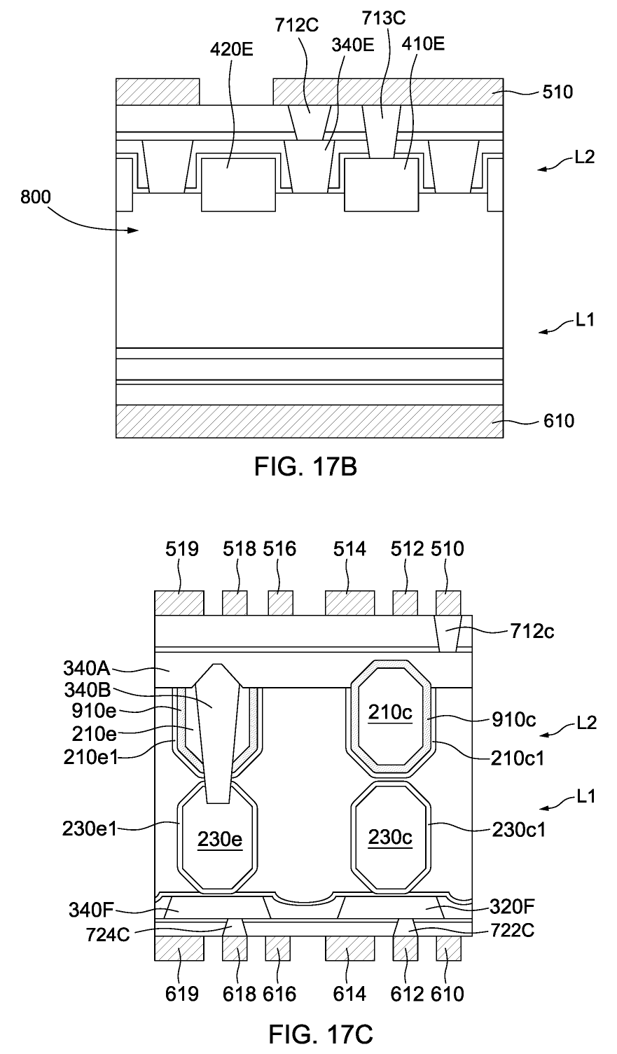

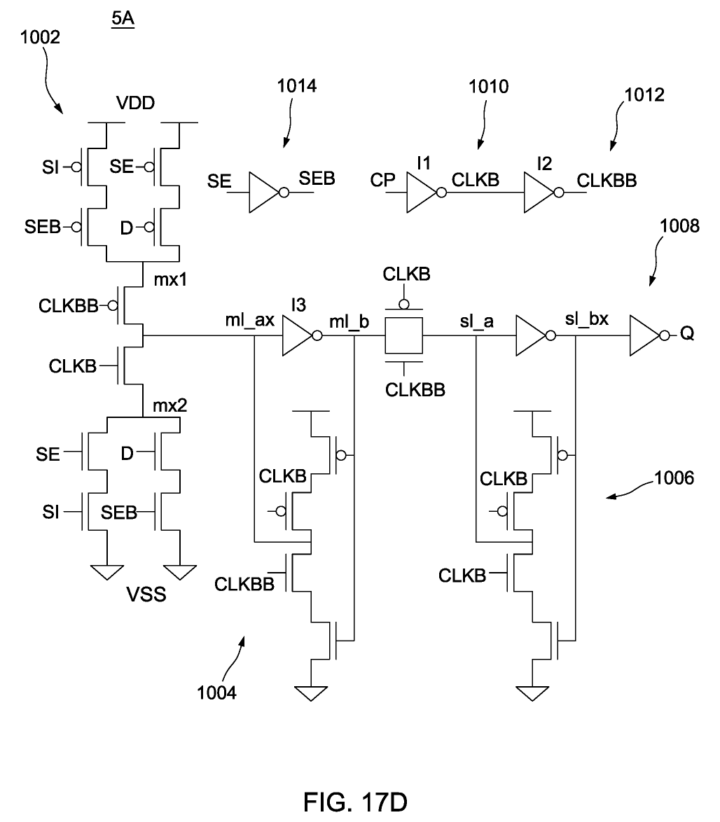

FIG. 17A is a top view of a semiconductor device 5 in accordance with some embodiments of the present disclosure. FIG. 17B is a cross-sectional view of a portion of a semiconductor device 5 in accordance with some embodiments of the present disclosure. FIG. 17C is a cross-sectional view of a portion of a semiconductor device 5 in accordance with some embodiments of the present disclosure. In some embodiments, FIG. 17B illustrates a cross-sectional view along the cross-sectional line 17B-17B' in FIG. 17A, and FIG. 17C illustrates a cross-sectional view along the cross-sectional line 17C-17C' in FIG. 17A. In some embodiments, FIG. 17A illustrates a top view of a lower layer L1 and a top view of an upper layer L2 of a portion of the semiconductor device 5. In some embodiments, the semiconductor device 5 is similar to the semiconductor device 1 in FIGS. 1A-1D and the semiconductor device 3 in FIGS. 15A-15E, with differences therebetween as follows. Descriptions of similar components are omitted.

Referring to FIGS. 17A-17C, the semiconductor device 3 may be a portion of a standard cell. The semiconductor device 3 may include at least a plurality of transistors at the upper layer L2 and the lower layer L1. The transistors at the same layer may have the same conductivity type. In some embodiments, the transistors at the upper layer L2 are n-type transistors, and the transistors at the lower layer L1 are p-type transistors, and vice versa.

Referring to FIGS. 17A-17C, the layout structure of the semiconductor device 5 may include at least active regions 210, 220, 230, and 240, contacts 310E, 330E, 340A, 340B, 340E, 350E, 360E, 370E, 310F, 320F, 330F, 340F, and 350F (also referred to as "source/drain (S/D) contacts"), a plurality of gates (e.g., at least gates 410E and 420E), conductive traces 510, 512, 514, 516, 518, 519, 610, 612, 614, 616, 618, and 619, conductive vias 711C, 712C, 713C, 714C, 715C, 716C, 717C, 721C, 722C, 723C, 724C, 725C, and 731C, an insulation structure 800, and a plurality of isolation layers (e.g., at least isolation layers 910c and 910e). In some embodiments, each of the contacts at the upper layer L2 (e.g., the contacts 310E, 330E, 340A, 340B, 340E, 350E, 360E, and 370E) is electrically connected to the conductive traces 510, 512, 514, 516, 518, and/or 519 through at least one conductive via (e.g., the conductive vias 711C, 712C, 713C, 714C, 715C, 716C, and/or 717C). In some embodiments, each of the contacts at the lower layer L1 (e.g., the contacts 310F, 320F, 330F, 340F, and/or 350F) is electrically connected to the conductive traces 610, 612, 614, 616, 618, and/or 619 through at least one conductive via (e.g., the conductive vias 721C, 722C, 723C, 724C, and/or 725C). In some embodiments, each of the gates (e.g., the gates 410E and/or 420E) is electrically connected to the conductive traces 510, 512, 514, 516, 518, and/or 519 through at least one conductive via (e.g., the conductive via 731C).

Referring to FIGS. 17A-17C, in some embodiments, the contact 340B penetrates and electrically connects the conductive segment 210e and the conductive segment 230e. In some embodiments, the contact 340B penetrates the isolation layer 910e and the spacer layers 210e1 and 230e1 to electrically connect the conductive segment 230e, the conductive segment 210e, and the contact 340A. In some embodiments, the conductive segment 230e is electrically connected to the gate 410E through the contact 320B, the contact 320A, the conductive via 712C, the conductive trace 510, and the conductive via 731C. In some embodiments, the semiconductor device 5 includes an inverter which includes a PMOS transistor having the conductive segment 230e and an NMOS transistor having the conductive segment 210e stacked over and coupled to the PMOS. In some embodiments, the contact 340A extends across the conductive segment 210c to electrically connect to the conductive via 712C. In some embodiments, the contact 340A is electrically isolated from the conductive segment 210c.

The structure in FIGS. 17A-17C may be applied to various integrated circuits/circuit cells to increasing routing flexibility. FIG. 17D illustrates a schematic view of a circuit 5A in accordance with some embodiments of the present disclosure. In some embodiments, at least an element of the circuit 5A illustrated in FIG. 17D may be implemented with at least a portion of the structure of the semiconductor device 5 illustrated in FIGS. 17A-17C.

Referring to FIG. 17D, in some embodiments, the circuit 5A is implemented as a flip flop circuit including a multiplexer 1002, a latch 1004, a latch 1006, an output circuit 1008, an inverter I1, an inverter I2, and an inverter 1014. The multiplexer 1002 includes two portions each including an input terminal configured to receive a signal D, an input terminal configured to receive a signal SI, and an input terminal configured to receive a selection signal SE or an inverted selection signal SEB. An output terminal of the multiplexer 1002 is coupled to an input terminal of the latch 1004. The multiplexer 1002 is configured to output a multiplexed signal to the latch 1004. An output terminal of the latch 1004 is coupled to an input terminal of the latch 1006. The latch 1004 is configured to output a signal to the latch 1006 by the output terminal. In some embodiments, the latch 1004 is coupled to the inverter I1, and is configured to receive a signal CLKB. In some embodiments, the latch 1004 is coupled to the inverter I2, and is configured to receive a signal CLKBB. The latch 1006 is coupled to the latch 1004 and the output circuit 1008. The input terminal of the latch 1006 is configured to receive a signal S2 from the latch 1004. The latch 1006 is configured to output a signal to the output circuit 1008 by the output terminal. In some embodiments, the latch 1006 is coupled to the inverter I1, and is configured to receive the signal CLKB. In some embodiments, the latch 1006 is coupled to the inverter I2, and is configured to receive the signal CLKBB. An output terminal of the output circuit 1008 is configured to output the output signal Q. In some embodiments, a transmission gate including an NMOX transistor and a PMOS transistor coupled together is configured to output a signal to an inverter I3. In some embodiments, at least the inverters of the circuit 5A may be implemented with the structures of the semiconductor device 5 illustrated in FIGS. 17A-17C.

According to an embodiment, a semiconductor device includes a first transistor, a second transistor, a third transistor, and a contact. The first transistor includes a first source/drain (S/D), a second S/D, and a first gate between the first S/D and the second S/D. The first transistor and the second transistor are stacked over the third transistor. The contact covers the second S/D of the first transistor. The contact is electrically connected to the second transistor and electrically isolated from the second S/D.

According to an embodiment, a semiconductor device includes a first transistor, a second transistor, a conductive trace, and a contact. The first transistor includes a first S/D, a second S/D, and a first gate between the first S/D and the second S/D. The second transistor is stacked directly under the first transistor. The conductive trace is over the first transistor. The contact covers the second S/D of the first transistor. The contact is electrically connected to the conductive trace and electrically isolated from the second S/D.

According to an embodiment, a method of manufacturing a semiconductor device includes: forming a first transistor stacked over a second transistor, the first transistor comprising a first S/D, a second S/D, and a first gate between the first S/D and the second S/D; forming a contact on the second S/D, the contact covering and electrically isolated from the second S/D of the first transistor; and forming a conductive trace over the first transistor and electrically connected to the contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor comprising a first source/drain (S/D), a second S/D, and a first gate between the first S/D and the second S/D;
a second transistor;
a contact covering the second S/D of the first transistor and electrically isolated from the second S/D, the contact being electrically connected to the second transistor; and
an isolation layer between the contact and the second S/D of the first transistor;
wherein the second S/D of the first transistor is laterally and vertically surrounded by the contact with the isolation layer therebetween.

2. The semiconductor device of claim 1, further comprising a third transistor, wherein the first transistor and the second transistor are stacked over the third transistor.

3. The semiconductor device of claim 1, wherein the isolation layer entirely covers a circumferential surface of the second S/D of the first transistor and electrically isolates the contact from the second S/D.

4. The semiconductor device of claim 1, wherein the second S/D is a shared S/D between the first transistor and the second transistor, and the shared S/D is electrically isolated from an external connector.

5. The semiconductor device of claim 1, wherein a width of a top surface of the contact is greater than a width of the second S/D, and the contact extends laterally beyond two opposing sides of the second S/D.

6. The semiconductor device of claim 1, further comprising an insulation structure covering the first transistor and the second transistor, wherein the contact extends through the insulation structure.

7. The semiconductor device of claim 1, further comprising a dummy gate laterally spaced apart from the first gate.

8. A semiconductor device, comprising:
a first transistor comprising a first S/D, a second S/D, and a first gate between the first S/D and the second S/D;
a second transistor stacked directly under the first transistor; and
a contact covering the second S/D of the first transistor and electrically isolated from the second S/D, the contact comprising a first extension extending below the second S/D and electrically connected to a S/D of the second transistor;
wherein the second S/D of the first transistor is laterally and vertically surrounded by the contact.

9. The semiconductor device of claim 8, wherein the first extension of the contact is between a bottom surface of the second S/D of the first transistor and a top surface of the S/D of the second transistor.

10. The semiconductor device of claim 8, further comprising a third transistor stacked over the second transistor, wherein the second S/D of the first transistor is a shared S/D between the first transistor and the third transistor.

11. The semiconductor device of claim 8, further comprising a conductive trace over the first transistor and electrically connected to the contact.

12. The semiconductor device of claim 8, wherein the first transistor is disposed at an upper layer and the second transistor is disposed at a lower layer below the upper layer, and the contact surrounds an entirety of the second S/D but covers only a top portion of the S/D of the second transistor.

13. The semiconductor device of claim 8, wherein the first gate is shared by the first transistor and the second transistor.

14. The semiconductor device of claim 8, further comprising a conductive trace disposed below the second transistor, wherein the first extension of the contact is narrower than a portion of the contact surrounding the second S/D.

15. A semiconductor device, comprising:
a first transistor comprising a first S/D, a second S/D, and a first gate between the first S/D and the second S/D;
a second transistor comprising a third S/D;
a conductive trace over the first transistor; and
a first contact covering the second S/D of the first transistor and electrically isolated from the second S/D, the first contact being electrically connected to the third S/D of the second transistor through the conductive trace;
wherein the second S/D of the first transistor is laterally and vertically surrounded by the first contact.

16. The semiconductor device of claim 15, further comprising a third transistor stacked directly under the first transistor, the third transistor comprising a fourth S/D directly under the second S/D of the first transistor, wherein the first contact is electrically connected to the fourth S/D of the third transistor.

17. The semiconductor device of claim 16, wherein the fourth S/D comprises a conductive layer and a spacer layer covering the conductive layer, the spacer layer has an opening exposing a portion of the conductive layer, and the portion of the conductive layer protrudes out of the opening of the spacer layer and extends into a recess of the first contact.

18. The semiconductor device of claim 15, wherein the second S/D of the first transistor is a shared S/D between the first transistor and the second transistor.

19. The semiconductor device of claim 15, wherein the conductive trace is a metal-zero layer over the first transistor, and the first contact is connected to the conductive trace through a conductive via laterally offset from the second S/D.

20. The semiconductor device of claim 15, wherein the second S/D and the third S/D are conductive segments of a common active region, and the first contact is laterally between a second contact on the third S/D and a third contact on the first S/D.
